(19) United States
(12) Patent Application Publication
(10) Pub. No.: US 2026/0353836 A1
(43) Pub. Date: Nov. 5, 2026

(54) IMAGE SENSOR INCLUDING A TRENCH PENETRATING A SUBSTRATE

(71) Applicant: SAMSUNG ELECTRONICS CO., LTD., Suwon-si (KR)

(72) Inventor: Kook Tae KIM, Suwon-si (KR)

(73) Assignee: SAMSUNG ELECTRONICS CO., LTD., Suwon-si (KR)

(21) Appl. No.: 19/543,281

(22) Filed: Feb. 18, 2026

(30) Foreign Application Priority Data
May 2, 2025 (KR) 10-2025-0058522

(51) Int. Cl. H10F 39/00

(52) U.S. Cl. CPC H10F 39/807; H10F 39/8027

(57) ABSTRACT

An image sensor includes a substrate including a plurality of photodiode regions; and an isolation pattern provided between the plurality of photodiode regions and configured to separate the substrate. The isolation pattern is provided in a first trench penetrating the substrate in a third direction perpendicular to a surface of the substrate. The isolation pattern may include a first isolation pattern provided along a side wall of the first trench and a second isolation pattern insulated from the substrate by the first isolation pattern and having a hollow bottle shape. A void is provided in the second isolation pattern, and a thickness of the second isolation pattern in a first direction intersecting the third direction is smaller than a width of the void in the first direction.

### CROSS-REFERENCE TO RELATED APPLICATION

This application claims priority under 35 U.S.C. §119 to Korean Patent Application No. 10-2025-0058522, filed on May 2, 2025, in the Korean Intellectual Property Office, the disclosure of which is incorporated by reference herein in its entirety.

### BACKGROUND

### 1. Field

The present disclosure relates generally to an image sensor.

### 2. Description of Related Art

An image sensor is a semiconductor device that converts optical images into electrical signals. The image sensor may be classified as a charge-coupled device (CCD) type and a complementary metal-oxide semiconductor (CMOS) type. The CMOS type image sensor may be abbreviated as a CMOS image sensor (CIS). The CIS is provided with a plurality of pixels arranged in two-dimensions. Each of the pixels includes a photodiode PD. The photodiode PD serves to convert incident light into an electrical signal.

### SUMMARY

One or more embodiments of the present disclosure provide an image sensor in which light absorption due to an isolation pattern may be decreased and sensitivity may be improved.

According to an aspect of the disclosure, an image sensor may include: a substrate including a plurality of photodiode regions; and an isolation pattern provided between the plurality of photodiode regions and configured to separate the substrate, wherein a surface of the substrate extends in a first direction and also extends in a second direction perpendicular to the first direction, wherein the isolation pattern is provided in a first trench penetrating the substrate in a third direction perpendicular to the surface of the substrate, wherein the isolation pattern includes: a first isolation pattern provided along a side wall of the first trench; and a second isolation pattern insulated from the substrate by the first isolation pattern and having a hollow bottle shape, wherein a void is provided within the second isolation pattern, and wherein a thickness of the second isolation pattern in the first direction intersecting the third direction is smaller than a width of the void in the first direction.

According to an aspect of the disclosure, an image sensor may include: a substrate including a plurality of photodiode regions; and an isolation pattern provided between the plurality of photodiode regions and configured to separate the substrate, wherein a surface of the substrate extends in a first direction and also extends in a second direction perpendicular to the first direction, wherein the isolation pattern is provided in a first trench penetrating the substrate in a third direction perpendicular to the surface of the substrate, wherein the isolation pattern includes: a first isolation pattern provided along a side wall of the first trench; and a second isolation pattern insulated from the substrate by the first isolation pattern and provided along the side wall of the first trench, and wherein, in a cross-section in the first direction, a thickness of the second isolation pattern in the first direction intersecting the third direction is thinner than a distance in the first direction between two surfaces of the second isolation pattern, which face each other.

According to an aspect of the disclosure, an image sensor may include: a substrate including a plurality of photodiode regions; and an isolation pattern provided between the plurality of photodiode regions and configured to separate the substrate, wherein a surface of the substrate extends in a first direction and also extends in a second direction perpendicular to the first direction, wherein the substrate includes: a first trench penetrating the substrate in a third direction perpendicular to the surface of the substrate; and a second trench provided adjacent to the first trench and having a shorter length in the third direction than the first trench, wherein the isolation pattern is provided in the first trench and the second trench, wherein the isolation pattern includes: a first isolation pattern; a second isolation pattern; and a third isolation pattern, wherein a void is provided in the isolation pattern, wherein the second isolation pattern is provided in a hollow bottle shape provided in the first trench, wherein the void is provided within the second isolation pattern, wherein the third isolation pattern is provided along a side surface of the second trench, and wherein the first isolation pattern is provided between the third isolation pattern and the substrate, between the second isolation pattern and the substrate, and in the second trench.

### BRIEF DESCRIPTION OF THE DRAWINGS

The above and other aspects and features will be more apparent from the following description of one or more example embodiments taken in conjunction with the accompanying drawings, in which:

FIG. 1 is an example block diagram of an image sensor according to one or more example embodiments;

FIG. 2 is a circuit diagram of one pixel included in an image sensor according to one or more example embodiments;

FIG. 3 shows the same pixel circuit as FIG. 2, with respect to one or more example embodiments\;

FIG. 4 is a top plan view showing an image sensor according to one or more example embodiments;

FIG. 5 shows a part of the pixel array region AR of FIG. 4, according to one or more example embodiments;

FIG. 6 is a cross-sectional view taken along line A-A’ of FIG. 5, according to one or more example embodiments;

FIG. 7 is a cross-sectional view taken along line B-B’ of FIG. 5, according to one or more example embodiments;

FIG. 8 is an enlarged view of the portion indicated by R1 in FIG. 6, according to one or more example embodiments;

FIG. 9 is an enlarged view of the portion indicated by R2 in FIG. 7, according to one or more example embodiments;

FIGS. 10, 11, 12, 13, 14, 15, 16, 17, 18, 19, 20, 21, 22, 23, 24, 25, 26, 27, 28, 29, 30, 31, 32 and 33 are cross-sectional views showing a manufacturing process of an image sensor according to one or more example embodiments, of which FIGS. 10, 12, 14, 16, 18, 20, 22, 24, 26, 28, 30, and 32 show the same cross-sections as FIGS. 8 , and 11, 13, 15, 17, 19, 21, 23, 25, 27, 29, 31, and 33 show the same cross-sections as FIG. 9;

FIGS. 34, 35, 36 and 37, 40, 41, 42 and 43, and 47 show the same cross-section as FIG. 8, with respect to one or more example embodiments;

FIGS. 38, 39, 44, 45 and 46, and 48 show the same cross-section as FIG. 9, with respect to one or more example embodiments;

FIG. 49 shows the same cross-section as FIG. 6, with respect to one or more example embodiments;

FIG. 50 shows the same cross-section as FIG. 7, with respect to one or more example embodiments;

FIG. 51 is an enlarged view of the portion indicated by R1 in FIG. 49, according to one or more example embodiments;

FIG. 52 is an enlarged view of the portion indicated by R2 in FIG. 50, according to one or more example embodiments;

FIGS. 53, 54, 55, 56, 57 and 58, 61, 62, 63, 64 and 65, and 69 show the same cross-section as FIG. 52, with respect to one or more example embodiments; and

FIGS. 59, 60, 66, and 68 show the same cross-section as FIG. 51, with respect to one or more example embodiments.

### DETAILED DESCRIPTION

Hereinafter, the present disclosure will be described more fully with reference to the accompanying drawings, in which example embodiments are shown. It will be apparent to those skilled in the art that the described example embodiments may be modified in various different ways, without departing from the spirit or scope of the present disclosure.

To more clearly describe example embodiments, parts that are irrelevant to the description are omitted, and like numerals refer to like or similar constituent elements throughout the specification.

Further, because sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, areas, etc., are exaggerated for clarity. In the drawings, for better understanding and ease of description, the thicknesses of some layers and areas are exaggerated.

It will be apparent to those skilled in the art, that when an element such as a layer, film, region, or substrate is referred to as being “on” another element, the element can be directly on the other element or intervening elements may also be present. In contrast, when an element is referred to as being “directly on” another element, there are no intervening elements present. Further, in the specification, the word “on” or “above” means located on or below the object portion, and does not necessarily mean located on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

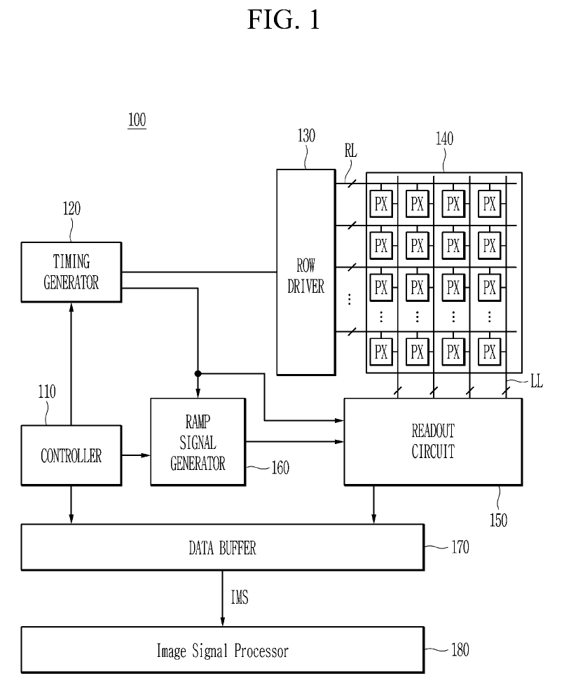

FIG. 1 is an example block diagram of an image sensor according to one or more example embodiments.

Referring to FIG. 1, an image sensor 100 according to one or more example embodiments may include a controller 110, a timing generator 120, a row driver 130, a pixel array 140, a readout circuit 150, a ramp signal generator 160, a data buffer 170 and an image signal processor 180. In one or more example embodiments, the image signal processor 180 may be provided outside the image sensor 100.

The image sensor 100 may generate an image signal by converting light received from an outside into an electrical signal. An image signal IMS may be provided to the image signal processor 180.

The image sensor 100 may be mounted on an electronic device having an image or light sensing function. For example, the image sensor 100 may be mounted on an electronic device such as a camera, a smartphone, a wearable device, an Internet of things (IoT) device, a home appliance, a tablet personal computer (PC), a personal digital assistant (PDA), a portable multimedia player (PMP), a navigation device, a drone, an advanced driver assistance system (ADAS), etc. Alternatively, the image sensor 100 may be mounted on an electronic device provided as a part of a vehicle, furniture, a manufacturing facility, a door, or various measuring devices.

The controller 110 may generally control each of the components 120, 130, 150, 160, and 170 included in the image sensor 100. The controller 110 may control an operation timing of each of the components 120, 130, 150, 160, and 170 by using control signals. In one or more example embodiments, the controller 110 may receive a mode signal indicating an imaging mode from an application processor, and may generally control the image sensor 100 based on the received mode signal. For example, the application processor may determine an imaging mode of the image sensor 100 according to various scenarios such as illumination of an imaging environment, resolution setting of a user, and a sensed or learned state, and may provide a determined result to the controller 110 as a mode signal. The controller 110 may control a plurality of pixels of the pixel array 140 to output pixel signals according to the imaging mode, the pixel array 140 may output a pixel signal for each of the pixels or a pixel signal for some of the pixels, and the readout circuit 150 may sample and process pixel signals received from the pixel array 140. The timing generator 120 may generate a signal that serves as a reference for operation timings of components of the image sensor 100. The timing generator 120 may control timings of the row driver 130, the readout circuit 150, and the ramp signal generator 160. The timing generator 120 may provide a control signal that controls the timings of the row driver 130, the readout circuit 150, and the ramp signal generator 160.

The pixel array 140 may include a plurality of pixels PX, and a plurality of row lines RL and a plurality of column lines LL respectively connected to the pixels PX. In one or more example embodiments, each of the pixels PX may include at least one photodiode. The photodiode may detect incident light, and may convert the incident light into an electrical signal according to an amount of light, i.e., a plurality of analog pixel signals. The photodiode may be a photodiode, a pinned diode, or the like. Additionally, the photodiode may be a single-photon avalanche diode (SPAD) applied to a 3D sensor pixel. A level of an analog pixel signal outputted from the photodiode may be proportional to an amount of charge outputted from the photodiode. That is, the level of the analog pixel signal output from the photodiode may be determined according to an amount of light received into the pixel array 140.

The row lines RL may extend in a first direction, and may be connected to the pixels PX provided along the first direction. For example, a control signal outputted from the row driver 130 to the row line RL may be transferred to gates of transistors of a plurality of pixels PX connected to the row line RL. The columns line LL may extend in a second direction crossing the first direction, and may be connected to the pixels PX positioned along the second direction. A plurality of pixel signals outputted from the pixels PX may be transferred to the readout circuit 150 through the column lines LL.

A color filter layer and a microlens layer may be positioned on the pixel array 140. The microlens layer may include a plurality of microlenses, and each of the microlenses may be provided at an upper portion of the at least one corresponding pixel PX. The color filter layer may include color filters such as red, green, and blue filters, and may additionally include a white filter. For one pixel PX, a unit color filter of one color may be provided between the pixel PX and the corresponding microlens. Alternatively, one unit color filter may be provided in the plurality of pixels PX adsorbing the same color.

The row driver 130 may generate a control signal for driving the pixel array 140 in response to a control signal from the timing generator 120, and control signals may be supplied to the pixels PX of the pixel array 140 through the row lines RL. In one or more example embodiments, the row driver 130 may control the pixels PX to sense light incident in a row line unit. The row line unit may include at least one row line RL. For example, the row driver 130 may provide a transfer signal, a reset signal, a selection signal, etc. to the pixel array 140, as will be described in greater detail below.

In response to the control signal from the timing generator 120, the readout circuit 150 may convert pixel signals (or electrical signals) from the pixels PX connected to the row line RL selected from among the pixels PX into pixel values representing an amount of light. The readout circuit 150 may convert the pixel signal outputted through the corresponding column line LL into a pixel value. For example, the readout circuit 150 may convert the pixel signal into the pixel value by comparing a ramp signal and the pixel signal. A pixel value may be image data having multiple bits. Specifically, the readout circuit 150 may include a selector, a plurality of comparators, a plurality of counter circuits, and the like.

The ramp signal generator 160 may generate a reference signal to transmit it to the readout circuit 150.

The ramp signal generator 160 may include a current source, a resistor, and a capacitor. The ramp signal generator 160 may generate a plurality of ramp signals that fall or rise with a slope determined according to a current magnitude of a variable current source or a resistance value of a variable resistor by adjusting a ramp voltage, which is a voltage applied to ramp resistance, adjusting the current magnitude of the variable current source or the resistance value of the variable resistor.

The data buffer 170 may store pixel values of the pixels PX connected to the selected column line LL transferred from the readout circuit 150, and may output the stored pixel values in response to an enable signal from the controller 110.

The image signal processor 180 may perform image signal processing on the image signal received from the data buffer 170. For example, the image signal processor 180 may receive a plurality of image signals from the data buffer 170, and may synthesize the received image signals to generate one image.

In one or more example embodiments, the pixels may be grouped in the form of M*N (M and N is an integer of 2 or more) to form one unit pixel group. The M*N form may be a form in which M items are arranged in an arrangement direction of the column lines LL and N items are arranged in an arrangement direction of the row lines RL. For example, one unit pixel group may include a plurality of pixels arranged in a 2*2 format, and one unit pixel group may output one analog pixel signal. One or more example embodiments are not limited to one pixel, but may also be applied to a group of unit pixels.

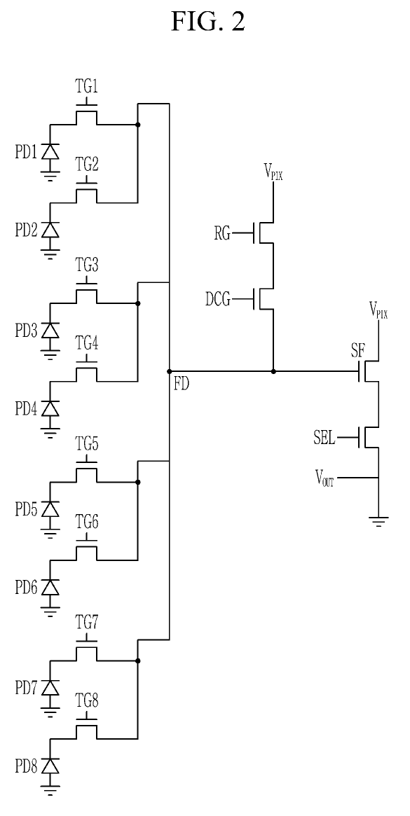

FIG. 2 is a circuit diagram of a single pixel included in an image sensor according to one or more example embodiments.

Referring to FIG. 2, one pixel may include a plurality of photodiodes (PDs) PD1, PD2, PD3, PD4, PD5, PD6, PD7, and PD8. The respective photodiodes PD1, PD2, PD3, PD4, PD5, PD6, PD7, and PD8 may perform photoelectric conversion. As shown in FIG. 2, the plurality of photodiodes PD1, PD2, PD3, PD4, PD5, PD6, PD7, and PD8 may be connected to one floating diffusion region FD. In FIG. 2, a configuration in which eight photovoltaic devices are connected to one floating diffusion region FD is described, but this is only an example, and the number of photovoltaic devices connected to one floating diffusion region FD may vary according to one or more example embodiments.

Hereinafter, a first photodiode PD1 will be mainly described, but the following description is equally applicable to other photodiodes PD2, PD3, PD4, PD5, PD6, PD7, and PD8.

The first photodiode PD1 may generate and accumulate charge according to an amount of light received. The first photodiode PD1 may include an anode connected to ground and a cathode connected to a first end of a first transfer transistor TG1. A first transmission signal TS1 may be supplied to a gate of the first transfer transistor TG1, and the first end of the first transfer transistor TG1 may be connected to the floating diffusion region FD. If the first transfer transistor TG1 is turned on by the first transmission signal, charges charged in the first photodiode PD1 may be transferred to the floating diffusion region FD. The floating diffusion region FD may maintain the charges transferred from the photodiode PD.

A plurality of transfer transistors TG1, TG2, TG3, TG4, TG5, TG6, TG7, and TG8 each may be connected between one of the plurality of photodiodes PD1, PD2, PD3, PD4, PD5, PD6, PD7, and PD8 and the floating diffusion region FD, and may include a gate electrode receiving a plurality of transmission signals. The number of plurality of transfer transistors TG1, TG2, TG3, TG4, TG5, TG6, TG7, and TG8 may be equal to the number of plurality of photodiodes PD1, PD2, PD3, PD4, PD5, PD6, PD7, and PD8.

The reset transistor RG may be connected between the power supply voltage Vpix and the floating diffusion region FD, and may include the reset transistor RG that receives a reset signal.

The reset transistor RG may periodically reset the charges accumulated in the floating diffusion region FD. A drain electrode of the reset transistor RG may be connected to a source electrode of a dual conversion gain transistor DCG, and the source electrode may be connected to a power supply voltage Vpix. If the reset transistor RG is turned on, the power supply voltage Vpix connected to the source electrode of the reset transistor RG may be applied to the floating diffusion region FD. Accordingly, if the reset transistor RG is turned on, the charges accumulated in the floating diffusion region FD may be discharged to reset the floating diffusion region FD.

The dual conversion gain transistor DCG may be provided between the reset transistor RG and the floating diffusion region FD, and may include a gate electrode that receives a dual conversion signal. The dual conversion gain transistor DCG may reset the floating diffusion region FD together with the reset transistor RG.

A drain electrode of the dual conversion gain transistor DCG may be connected to the floating diffusion region FD, and the source electrode of the dual conversion gain transistor DCG may be connected to the drain electrode of the reset transistor RG. If the reset transistor RG and the dual conversion gain transistor DCG are turned on, the power supply voltage Vpix connected to the source electrode of the reset transistor RG may be applied to the floating diffusion region FD through the dual conversion gain transistor DCG. Accordingly, the charges accumulated in the floating diffusion region FD may be discharged to reset the floating diffusion region FD.

A source follower transistor SF may output a pixel signal according to a voltage of the floating diffusion region FD. A gate of the source follower transistor SF may be connected to the floating diffusion region FD, a source electrode of the source follower transistor SF may be connected to a first end of a selection transistor SEL, and the power supply voltage Vpix may be supplied to a drain electrode of the source follower transistor SF. The source follower transistor SF may form a source follower circuit and may output a voltage of a level corresponding to the charge accumulated in the floating diffusion region FD as a pixel signal.

When the selection transistor SEL is turned on by the selection signal, a pixel signal from the source follower transistor SF may be transmitted to the readout circuit 150. The selection signal may be applied to the gate electrode of the selection transistor SEL, and the drain electrode of the selection transistor SEL may be connected to an output wire Vout that outputs a plurality of pixel signals.

An operation of the image sensor 100 according to one or more example embodiments will be described with reference to FIG. 2 as follows. First, with light blocked, the power supply voltage Vpix may be applied to the drain electrode of the reset transistor RG and the drain electrode of the source follower transistor SF. And the reset transistor RG and the dual conversion gain transistor DCG may be turned on to discharge the remaining charges in the floating diffusion region FD. After that, the reset transistor RG may be turned off, and light from the outside may be incident on the photodiodes PD1, PD2, PD3, PD4, PD5, PD6, PD7, and PD8, so that electron-hole pairs may be generated respectively from the photodiodes PD1, PD2, PD3, PD4, PD5, PD6, PD7, and PD8. Holes may be moved to, and accumulated in, p-type impurity regions of photodiodes PD1, PD2, PD3, PD4, PD5, PD6, PD7, and PD8, and electrons may be moved to, and accumulated in, n-type impurity regions. When the transfer transistors TG1, TG2, TG3, TG4, TG5, TG6, TG7, and TG8 are turned on, the charges such as electrons and holes may be transmitted to the floating diffusion region FD and accumulated. The gate bias of the source follower transistor SF changes in proportion to the amount of accumulated charge, which causes a change in the source potential of the source follower transistor SF. In this case, if the selection transistor SEL is turned on, a signal by charges may be read through the output wire Vout.

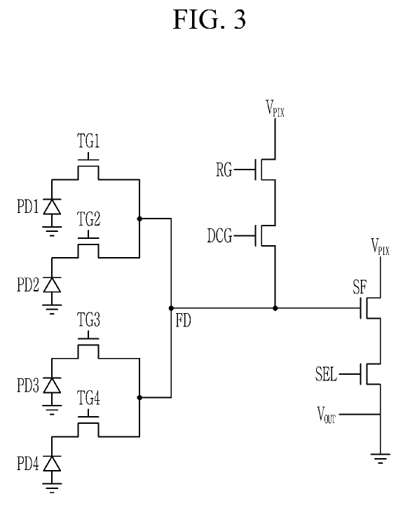

FIG. 2 shows a configuration including eight photodiodes, but in one or more example embodiments, the number of photodiodes included in one image sensor may vary. FIG. 3 shows the same pixel circuit as FIG. 2, with respect to another one or more example embodiments. Referring to FIG. 3, an image sensor according to one or more example embodiments is the same as the one or more example embodiments of FIG. 2, except that the four photodiodes PD1, PD2, PD3, and PD4 are included. The duplicate detailed description of the same components already discussed above may be omitted.

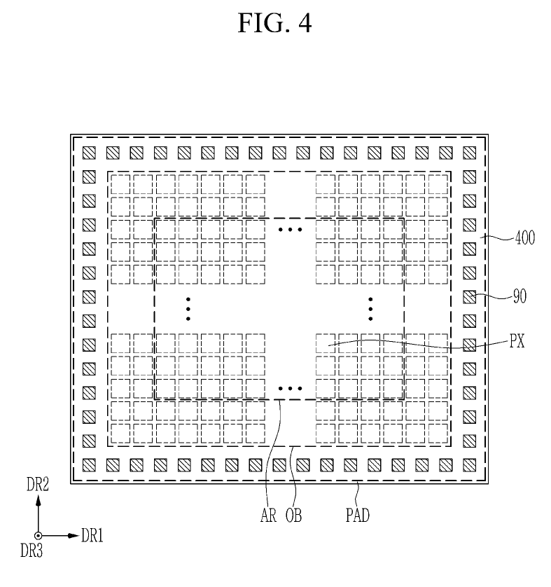

FIG. 4 is a top plan view showing an image sensor according to one or more example embodiments.

Referring to FIG. 4, the first substrate 400 may include a pixel array region AR, an optical black region OB, and a pad region PAD in a plan view. The pixel array region AR may be positioned in a central region of the first substrate 400 in a plan view. The pixel array region AR may include a plurality of pixels PX. The pixels PX may output a photoelectric signal from incident light. The pixels PX may be positioned in rows parallel to a first direction DR1 and in columns parallel to the second direction DR2.

The pad region PAD may be positioned at an edge of the first substrate 400, and may surround the pixel array area AR. A plurality of pad terminals 90 may be positioned in the pad region PAD. The pad terminals 90 may output electrical signals generated by the pixel PX to the outside. Alternatively, an external electrical signal or voltage may be transmitted to the pixel PX through the pad terminals 90. Because the pad area PAD is disposed on an edge of the first substrate 400, the pad terminals 90 can be easily connected to the outside.

The optical black region OB may be positioned between the pixel array region AR and the pad region PAD of the first substrate 400. The optical black region OB may surround the pixel array region AR. A pixel positioned in the optical black region OB may include a dummy region instead of the photodiode region 410. The signal generated in the dummy region may be used as information to remove process noise.

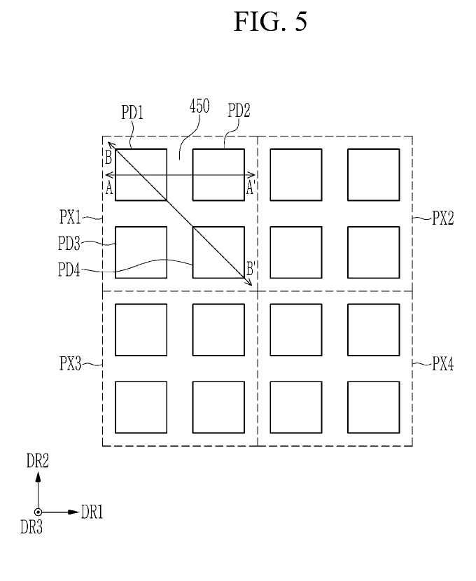

FIG. 5 shows a part of the pixel array region AR of FIG. 4, according to one or more example embodiments. Referring to FIG. 5, a plurality of photodiodes PD1, PD2, PD3, and PD4 may be included in one pixel. FIG. 5 shows a first pixel PX1, a second pixel PX2, a third pixel PX3, and a fourth pixel PX4. Although it is illustrated that each of the pixels PX1, PX2, PX3, and PX4 includes four photodiodes PD, this is merely an example and one or more example embodiments are not limited thereto. Each of the pixel PX1, PX2, PX3, and PX4 may include two photodiodes PD, and may include eight photodiodes PD. As shown in FIGS. 2 and 3, the floating diffusion regions FD of photodiodes PD included in each pixel may be integrally connected.

A unit color filter may be provided on the first pixel PX1, the second pixel PX2, the third pixel PX3, and the fourth pixel PX4. Unit color filters of different colors may be provided on the first pixel PX1, the second pixel PX2, and the third pixel PX3, respectively. In one or more example embodiments, unit color filters of the same color may be provided on the first pixel PX1 and the fourth pixel PX4, but this is merely an example and one or more example embodiments are not limited thereto.

As shown in FIG. 5, a PD isolation pattern 450 may be provided between the photodiodes PD. The PD isolation pattern 450 may have a lattice structure, in a plan view. The PD isolation pattern 450 may also be provided between the plurality of photodiodes included in one pixel, in a plan view, while partitioning each pixel. Although FIG. 5 illustrates a configuration in which the PD isolation pattern 450 included in one pixel PX1, PX2, PX3, and PX4 does not include a cut portion, this is merely an example, and in one or more example embodiments, the PD isolation pattern 450 may include a cut portion between the plurality of photodiodes PD.

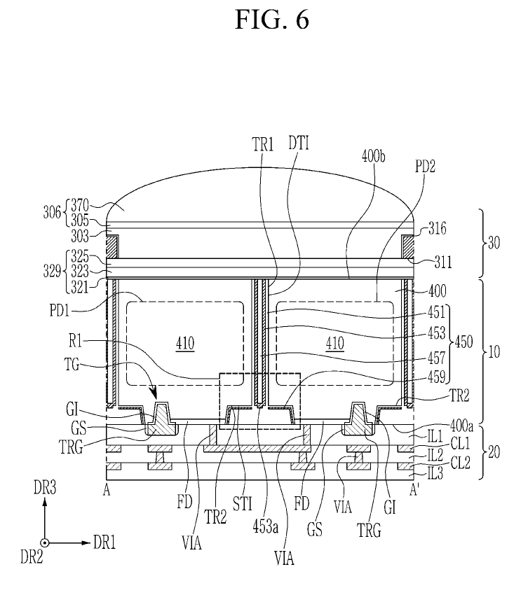

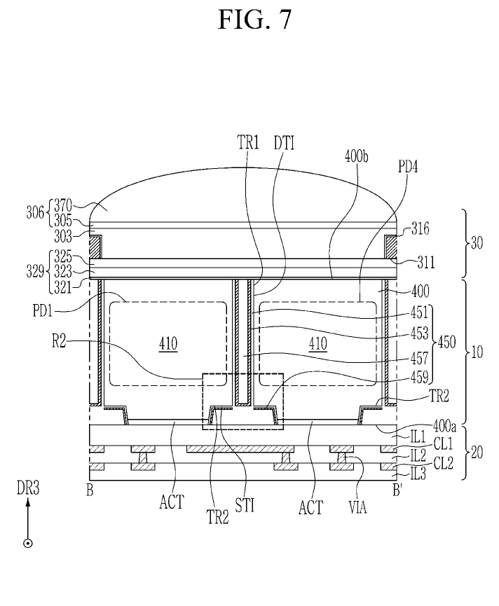

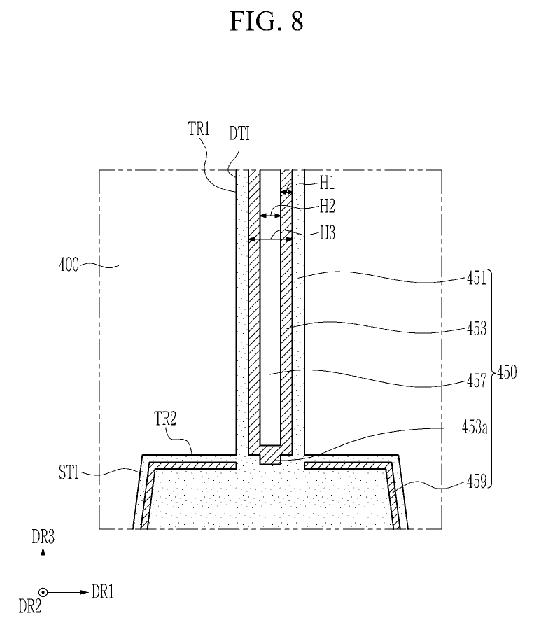

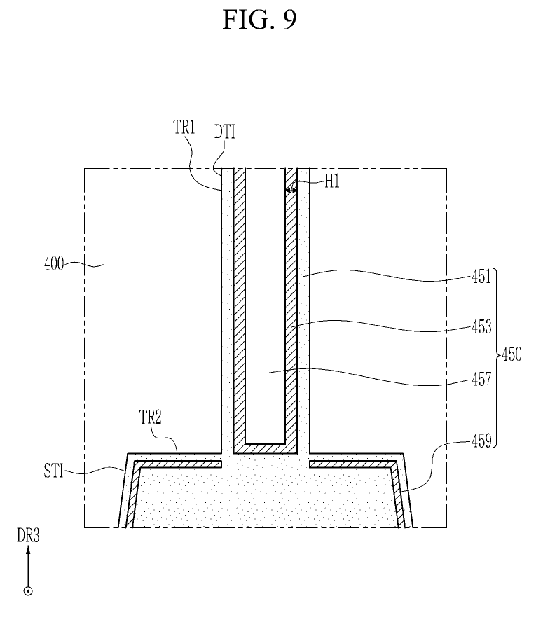

FIG. 6 is a cross-sectional view taken along line A-A’ of FIG. 5, according to one or more example embodiments. FIG. 7 is a cross-sectional view taken along line B-B’ of FIG. 5, according to one or more example embodiments. FIG. 8 is an enlarged view of the portion indicated by R1 in FIG. 6, according to one or more example embodiments. FIG. 9 is an enlarged view of the portion indicated by R2 in FIG. 7, according to one or more example embodiments.

Referring to FIGS. 6, 7, 8 and 9, an image sensor according to one or more example embodiments may include the first substrate 400. The first substrate 400 may include a first surface 400a and a second surface 400b facing each other. Light may be incident on the second surface 400b of the first substrate 400. The first wiring region 20 may be positioned on the first surface 400a of the first substrate 400, and the light transmitting layer 30 may be positioned on the second surface 400b of the first substrate 400. The first substrate 400 may be a semiconductor substrate or a silicon on insulator (SOI) substrate. For example, the semiconductor substrate may include a silicon substrate, a germanium substrate, or a silicon-germanium substrate. The first substrate 400 may include impurities of a first conductivity type. For example, the first conductivity-type impurity may be a p-type impurity such as aluminum (Al), boron (B), indium (In), and gallium (Ga).

The first substrate 400 may include the PD isolation pattern 450. The PD isolation pattern 450 may partition a plurality of unit pixels and a plurality of photodiode regions 410 within a single pixel. FIGS. 6 and 7 illustrate a portion of a cross-section of one pixel, and two photodiode regions 410 are illustrated in a cross-sectional view. However, this is a virtual cross-section for convenience of description, and one or more example embodiments are not limited thereto. That is, as shown in FIG. 2, one pixel may include eight photodiode regions 410, and the number of photodiode regions 410 may vary.

The first substrate 400 may include a photodiode region 410. The photodiode region 410 may perform the same function and role as the photodiode PD region illustrated in FIGS. 2 and 3. FIG. 6 shows the first photodiode PD1 and a second photodiode PD2, and FIG. 7 shows the first photodiode PD1 and a fourth photodiode PD4.

The photodiode region 410 may be a region doped with impurities of a second conductivity type in the first substrate 400. The impurities of the second conductivity type may have a conductivity type opposite to that of the impurities of the first conductivity type. The second conductivity-type impurity may be an n-type impurity such as phosphorus, arsenic, bismuth, and antimony. For example, each photodiode region 410 may include a first region adjacent to the first surface 400a and the second region adjacent to the second surface 400b. There may be a difference in impurity concentration between the first region and the second region of the photodiode region 410. Therefore, the photodiode region 410 may have a potential gradient between the first surface 400a and the second surface 400b of the first substrate 400. However, as another one or more example embodiments, the photodiode region 410 may not have a potential gradient between the first surface 400a and the second surface 400b of the first substrate 400.

The first substrate 400 and the photodiode region 410 may constitute a photodiode PD. That is, the photodiode PD may be formed by a p-n junction between the first substrate 400 of the first conductivity type and the photodiode region 410 of the second conductivity type. The photodiode region 410 constituting the photodiode may generate and accumulate photocharges in proportion to intensity of incident light.

Referring to FIGS. 6, 7, 8 and 9 simultaneously, the PD isolation pattern 450 may be provided in the first substrate 400. Referring to FIGS. 6, 7, 8 and 9, the PD isolation pattern 450 may be disposed in a first trench TR1 and a second trench TR2. The first trench TR1 and the second trench TR2 may penetrate the substrate 400 or may be recessed from the substrate 400, in a partial region of the first surface 400a of the first substrate 400. As shown in FIG. 7, a length of the first trench TR1 in a third direction DR3 may be longer than a length of the second trench TR2 in the third direction DR3. The PD isolation pattern 450 may include a deep trench isolation layer DTI and a shallow trench isolation layer STI. The PD isolation pattern 450 may penetrate the first substrate 400. A length of the PD isolation pattern 450 in the third direction DR3 may be the same as a thickness of the first substrate 400 in the third direction DR3.

For example, a width of the deep trench isolation layer DTI in the PD isolation pattern 450 may gradually decrease from the first surface 400a to the second surface 400b of the first substrate 400. However, this is merely an example, and one or more example embodiments are not limited thereto. According to another one or more example embodiments, the width of the deep trench isolation layer DTI of the PD isolation pattern 450 may gradually increase from the first surface 400a of the first substrate 400 toward the second surface 400b. Alternatively, the width of the deep trench isolation layer DTI of the PD isolation pattern 450 may be constant between the first surface 400a and the second surface 400b of the first substrate 400. In addition, the PD isolation pattern 450 may not penetrate the substrate 400.

The PD isolation pattern 450 may include a first PD isolation pattern 451, a second PD isolation pattern 453, a third PD isolation pattern 459, and a void 457. The PD isolation pattern 450 of an image sensor according to one or more example embodiments may include the void 457, to minimize light absorption by the second PD isolation pattern 453. Hereinafter, a detailed structure of the PD isolation pattern 450 will be described.

First, a shape of the PD isolation pattern 450 in the cross-section along line A-A’ will be described with reference to FIGS. 6 and 8. Referring to FIGS. 6 and 8, the first PD isolation pattern 451 may be provided along side walls of the first trench TR1 and the second trench TR2. The first PD isolation pattern 451 may be provided along the side walls of the first trench TR1 and the second trench TR2, and the first PD isolation pattern 451 may be provided within a remaining space of the first trench TR1 and the second trench TR2. That is, in the PD isolation pattern 450, the remaining space in which the second PD isolation pattern 453, the third PD isolation pattern 459, and the void 457 are not provided may be filled with the first PD isolation pattern 451.

The first PD isolation pattern 451 may include, e.g., a silicon-based insulating material (e.g., a silicon nitride, a silicon oxide, or a silicon oxynitride) or a high dielectric material (e.g., a hafnium oxide or an aluminum oxide). According to another one or more example embodiments, the first PD isolation pattern 451 may include a plurality of layers, and the layers may include different materials. The first PD isolation pattern 451 may have a lower refractive index than that of the first substrate 400. Accordingly, crosstalk phenomena between photodiode regions 410 positioned on the first substrate 400 may be prevented or reduced. For example, the first PD isolation pattern 451 may include silicon oxide.

The second PD isolation pattern 453 may be provided within the first PD isolation pattern 451. For example, a sidewall of the second PD isolation pattern 453 may be surrounded by the first PD isolation pattern 451. The first PD isolation pattern 451 may be provided between the second PD isolation pattern 453 and the first substrate 400. The second PD isolation pattern 453 may be separated from the first substrate 400 by the first PD isolation pattern 451. Accordingly, if the image sensor operates, the second PD isolation pattern 453 may be electrically separated from the first substrate 400.

The second PD isolation pattern 453 may include a crystalline semiconductor material, e.g., polycrystalline silicon. According to one or more example embodiments, the second PD isolation pattern 453 may further include a dopant, and the dopant may include impurities of the first conductivity type or impurities of the second conductivity type.

For example, the second PD isolation pattern 453 may include doped polycrystalline silicon. Alternatively, the second PD isolation pattern 453 may include an undoped crystalline semiconductor material. For example, the second PD isolation pattern 453 may include undoped polycrystalline silicon. The term “undoped” may indicate that no intentional doping process has been performed. The dopant may include an n-type dopant and a p-type dopant. However, the second PD isolation pattern 453 may include an insulating material.

Referring to FIGS. 6 and 8, the second PD isolation pattern 453 may be an empty bottle shape including an empty interior space. That is, the void 457 may be provided within the second PD isolation pattern 453. In the present disclosure, the void 457 may refer to an empty space that is not filled with a solid material. That is, the void 457 may be an air gap. However, according to one or more example embodiments, a material may be filled into a partial region of the void 457. As will be described below, some of the material of an insulation structure 329 may be provided within the void 457. Alternatively, in one or more example embodiments, the first PD isolation pattern 451 or another material may be filled into the void 457. Various modifications to one or more example embodiments will be described below.

Referring to FIGS. 6 and 8, the second PD isolation pattern 453 may include a protruding portion 453a protruding in a direction toward the first surface 400a of the substrate 400. As will be explained below, this is a portion formed in a process for forming the second PD isolation pattern 453 of an empty bottle shape during the manufacturing process. However, this is a mere example, and in one or more example embodiments, the protruding portion 453a may not be formed, or may be formed longer in a direction toward the second trench TR2. Alternatively, the second PD isolation pattern 453 may not include the protruding portion 453a but may include an open portion that is partially open. The one or more example embodiments of FIGS. 6, 7, 8 and 9 illustrate a configuration in which the second PD isolation pattern 453 illustrated in the cross-section in the A-A’ direction includes the protruding portion 453a, but in one or more example embodiments, the second PD isolation pattern 453 illustrated in the cross-section in the B-B’ direction may include the protruding portion. Various modifications to one or more example embodiments will be described in greater detail below.

Referring to FIGS. 6 and 8, the third PD isolation pattern 459 may be provided along an edge of the second trench TR2. The third PD isolation pattern 459 may include silicon nitride, but is not limited thereto. The first PD isolation pattern 451 may be provided between the third PD isolation pattern 459 and the substrate 400. The first PD isolation pattern 451 may improve the interface characteristics between the third PD isolation pattern 459 and the substrate 400. A thickness of the first PD isolation pattern 451 in the first direction DR1 provided between the third PD isolation pattern 459 and the substrate 400 may be 3 nm to 5 nm. In addition, a thickness of the third PD isolation pattern 459 in the first direction DR1 may be 5 nm to 8 nm. However, these values may only be an example, and one or more example embodiments are not limited to this example.

Referring to FIGS. 6 and 8, the second PD isolation pattern 453 may be provided within the first trench TR1. In addition, the third PD isolation pattern 459 may be provided within the second trench TR2. Referring to FIG. 6, the second PD isolation pattern 453 may have an empty bottle shape having the void 457 inside. Accordingly, a significant portion of the first trench TR1 may be empty.

The second PD isolation pattern 453 may include doped polycrystalline silicon, and the doped polycrystalline silicon may have a high light absorption rate, thereby decreasing the sensitivity of the image sensor. However, in an image sensor according to one or more example embodiments, the second PD isolation pattern 453 does not entirely fill the first trench TR1 but has a bottle shape having an empty interior, thereby decreasing the area occupied by polycrystalline silicon. Accordingly, the amount of polycrystalline silicon within the PD isolation pattern 450 is minimized, so that the sensitivity of the image sensor may be improved. In addition, when the second PD isolation pattern 453 fills the entire first trench TR1, non-uniformity occurs inside, so that a seam may be formed. However, in one or more example embodiments, the second PD isolation pattern 453 is formed to be thin within the PD isolation pattern 450, and the occurrence of a non-uniform seam may be prevented.

Referring to FIG. 8, a thickness H1 of the second PD isolation pattern 453 in the first direction DR1 may be 4 nm to 8 nm. The second PD isolation pattern 453 may be formed in a uniform thickness within the first trench TR1. In the present disclosure, the meaning of the uniform thickness may mean that a thickness difference between a thickest portion and a thinnest portion of the second PD isolation pattern 453 is 10 % or less.

In an area within the first trench TR1, a portion occupied by the void 457 may be wider than an area of a portion occupied by the second PD isolation pattern 453. That is, as shown in FIG. 8, a width H2 of the void 457 in the first direction DR1 may be greater than the thickness H1 of the second PD isolation pattern 453 in the first direction DR1. Specifically, the width H2 in of the void 457 in the first direction DR1 may be 3 times to 40 times of the thickness H1 of the second PD isolation pattern 453 in the first direction DR1.

In addition, a ratio of the width H2 in of the void 457 in the first direction DR1 with respect to a width H3 of the first trench TR1 in the first direction DR1 may be 30 % or more. For example, it may be 30 % to 90 %.

FIG. 7 may be a cross-section of FIG. 5 in a B-B’ direction, and FIG. 9 is an enlarged view of the portion in FIG. 7 indicated as R2. Although an active pattern ACT is illustrated on the first surface 400a of the substrate 400 of FIG. 7, it is merely an example, and the gate electrode of the transistors described with reference to FIGS. 2 and 3 may be provided on the first surface 400a of the substrate 400.

Referring to FIG. 9, the description of the PD isolation pattern 450 illustrated in FIG. 9 is the same as FIG. 8. A duplicate detailed description of the same configuration is omitted. Referring to FIG. 9, the second PD isolation pattern 453 of the PD isolation pattern 450 shown in FIG. 9 may not include a protruding portion. That is, in the case of FIG. 9, an upper surface of the second PD isolation pattern 453 may be flat and have a hollow bottle shape. Afterwards, as will be described separately regarding the manufacturing process, in order to form the second PD isolation pattern 453 in a hollow bottle shape, an opening is formed in a partial region. At this time, a protruding portion may be formed in a region where an opening is formed during the process of re-filling the opening, but a protruding portion may not be formed in a region where an opening is not formed. That is, FIG. 8 may be a region where an opening is formed during the manufacturing process, and FIG. 9 may be a region where an opening is not formed during the manufacturing process.

In the one or more example embodiments of FIGS. 6, 7, 8 and 9, because an opening for forming the second PD isolation pattern 453 of a hollow bottle shape is formed in the cross-section in the A-A’ direction and not in the cross-section in the B-B’ direction, the second PD isolation pattern 453 in the cross-section in the A-A’ direction may include the protruding portion 453a, and the second PD isolation pattern 453 in the cross-section in the B-B’ direction may not include a protruding portion.

However, this is merely an example, and in one or more example embodiments, an opening for forming the second PD isolation pattern 453 of a hollow bottle shape may be formed in the cross-section in the B-B’ direction but not in the cross-section in the A-A’ direction. In this case, the second PD isolation pattern 453 of the cross-section in the A-A’ direction may not include a protruding portion, and the second PD isolation pattern 453 in the cross-section in the B-B’ direction may include the protruding portion 453a.

Although FIGS. 6, 7, 8 and 9 illustrate a configuration in which the PD isolation pattern 450 and the first surface 400a of the first substrate 400 are provided on the same plane, this is merely an example, and one or more example embodiments are not limited thereto. For example, the PD isolation pattern 450 and the first surface 400a of the first substrate 400 may not be coplanar. The PD isolation pattern 450 may be provided to be protruding or recessed from the first surface 400a of the first substrate 400.

In addition, although FIGS. 6, 7, 8 and 9 illustrate an upper surface of the PD isolation pattern 450 to be flat, this is merely an example, and the upper surface of the PD isolation pattern 450 may include a curved surface. That is, the upper surface of the PD isolation pattern 450 may have a structure that is recessed or protruding toward the substrate 400.

Referring back to FIG. 6, the transfer transistor TG described with reference to FIG. 2 may be provided on the first surface 400a of the first substrate 400. The transfer transistor TG may be electrically connected to the photodiode region 410. The transfer transistor TG may include a gate electrode TRG and the floating diffusion region FD. The floating diffusion region FD may be adjacent to one side of the gate electrode TRG. The floating diffusion region FD may have the second conductivity type (e.g., n-type), which is opposite to the first substrate 400.

A gate insulation layer GI may be provided between the gate electrode TRG and the first substrate 400. A gate spacer GS may be positioned on the sidewall of the gate electrode TRG. The gate spacer GS may include silicon nitride, silicon carbonitride or silicon oxynitride. A plurality of floating diffusion regions FD connected to a different transfer transistor TG may be connected through a via VIA, a first wiring layer CL1, or the like.

The wire region 20 may be provided on the first surface 400a of the first substrate 400, and may include a plurality of insulation layers IL1, IL2, and IL3, a plurality of wiring layers CL1 and CL2 and a plurality of vias VIA.

The plurality of insulation layers may include a first insulating layer IL1, a second insulating layer IL2, and a third insulating layer IL3.

The first insulation layer IL1 may cover the first surface 400a of the first substrate 400. The first insulation layer IL1 may cover the gate electrode TRG. The second insulation layer IL2 may be provided on the first insulation layer IL1. The third insulation layer IL3 may be provided on the second insulation layer IL2.

The first, second and third insulation layers IL1, IL2, and IL3 may include a non-conductive material. For example, the first, second and third insulation layers IL1, IL2, and IL3 may include a silicon-based insulating material such as silicon oxide, silicon nitride, or silicon oxynitride.

The wiring layers CL1 and CL2 may include the first wiring layer CL1 and a second wiring layer CL2. The first wiring layer CL1 may be provided within the second insulation layer IL2. The second wiring layer CL2 may be provided within the third insulation layer IL3.

The wire provided in each of the first wiring layer CL1 and the second wiring layer CL2 may be connected to the floating diffusion region FD through the via VIA. The via VIA may penetrate the insulation layers IL1, IL2, and IL3.

In addition, an image sensor according to one or more example embodiments may include the light transmitting layer 30. The light transmitting layer 30 may include the insulation structure 329, a unit color filter 303 and a microlens portion 306. The light transmitting layer 30 may collect and filter light incident from the outside, and may provide the light to the photodiode region 410.

The unit color filter 303 may be provided on the second surface 400b of the substrate 400. Color filters included in pixels arranged in N*M that absorb the same color may have one color filter positioned over the entire N*M pixel area or separate color filters positioned for respective pixels. In the present disclosure, the unit color filter 303 may include one color filter disposed in the plurality of pixels that absorb the same color or color filters disposed for respective pixels.

The unit color filter 303 may include primary color filters. The unit color filter 303 may include a first color filter, a second color filter, and a third color filter having different colors. For example, the first color filter, the second color filter, and the third color filter may include green, red and blue color filters, respectively. The first color filter, the second color filter, and the third color filter may be arranged in a Bayer pattern. As another example, the first color filter, the second color filter, and the third color filter may include colors such as cyan, magenta, or yellow.

The insulation structure 329 may be provided between the second surface 400b and the unit color filter 303 of the substrate 400. The insulation structure 329 may prevent reflection of light, so that light incident on the second surface 400b of the substrate 400 may smoothly reach the photodiode region 410. The insulation structure 329 may be referred to as an anti-reflection structure.

The insulation structure 329 may include a first fixed charge layer 321, a second fixed charge layer 323, and a planarized layer 325 that are sequentially stacked on the second surface 400b of the substrate 400. The first fixed charge layer 321, the second fixed charge layer 323, and the planarized layer 325 may include different materials. The first fixed charge layer 321 may include one of aluminum oxide, tantalum oxide, titanium oxide, and hafnium oxide. The second fixed charge layer 323 may include another one of aluminum oxide, tantalum oxide, titanium oxide, and hafnium oxide. For example, the first fixed charge layer 321 may include aluminum oxide, the second fixed charge layer 323 may include hafnium oxide, and the planarized layer 325 may include silicon oxide. According to one or more example embodiments, a silicon anti-reflection layer may be interposed between the second fixed charge layer 323 and the planarized layer 325. The anti-reflection layer may include silicon nitride.

FIGS. 6, 7, 8 and 9 illustrate a configuration in which the insulation structure 329 does not penetrate into the void 457, but in one or more example embodiments, a part of the insulation structure 329 may be provided within the void 457. That is, in the forming process of the insulation structure 329, some material may also be formed inside the void 457, depending on the type of material. Such a modified one or more example embodiments will be described below.

The microlens portion 306 may be provided on the unit color filter 303. The microlens portion 306 may include a planarized portion 305 in contact with the unit color filter 303 and a microlens 370 provided on the planarized portion 305. The planarized portion 305 may include, for example, an organic material. As another example, the planarized portion 305 may include silicon oxide or silicon oxynitride. The microlens 370 may have a convex shape so as to focus incident light. Each microlens 370 may vertically overlap with the photodiode region 410. A shape of the microlens 370 may vary. For better understanding and ease of description, FIG. 6 illustrates that one microlens 370 overlaps with two photodiode regions 410 in cross-section. However, in a plan view, one microlens 370 may be provided in a shape to overlap with four photodiode regions 410. However, this is merely an example, and the number of the microlenses 370 provided in one pixel PX may vary.

The light transmitting layer 30 may further include a Bayer pattern 311 and a protective layer 316. The Bayer pattern 311 may be provided between the unit color filters 303 adjacent to each other, to separate them from each other. The Bayer pattern 311 may be provided on the insulation structure 329. For example, the Bayer pattern 311 may have a lattice pattern. The Bayer pattern 311 may include a material having a lower refractive index than the unit color filter 303. The Bayer pattern 311 may include an organic material. For example, the Bayer pattern 311 may be a polymer layer including silica nanoparticles. The Bayer pattern 311 may have a low refractive index, thereby decreasing the amount of light incident on the photodiode region 410, and reducing crosstalk between pixels PX. That is, light receiving efficiency may be increased in each photodiode region 410, and a signal-to-noise ratio (SNR) characteristic may be improved.

The protective layer 316 may cover a surface of the Bayer pattern 311 with a substantially uniform thickness. The protective layer 316 may include at least one single layer or multilayer of, for example, an aluminum oxide layer and a silicon carbide oxide layer. The protective layer 316 may protect the unit color filter 303, and may have a moisture adsorption function. FIG. 6 and 7 illustrate that the protective layers 316 are separated from each other, but in one or more example embodiments, the protective layer 316 may be integrally connected between neighboring Bayer patterns 311.

In the above description, the shape of the PD isolation pattern 450 provided within one pixel PX has been described with a cross-section of one pixel PX as a center, but the description of the PD isolation pattern 450 may also be equally applied to the PD isolation pattern 450 provided between different pixels PX. That is, although FIGS. 5, 6 and 7 illustrate the cross-section within one pixel PX1, the shape of the PD isolation pattern 450 provided between different pixels, for example, between the first pixel PX1 and the second pixel PX2 may be the same as described above.

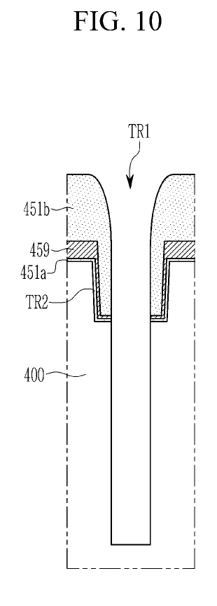

Hereinafter, a method for manufacturing an image sensor according to one or more example embodiments will be described with reference to FIGS. 10-33. FIGS. 10, 12, 14, 16, 18, 20, 22, 24, 26, 28, 30, and 32 show the same cross-sections as FIGS. 8, and 11, 13, 15, 17, 19, 21, 23, 25, 27, 29, 31, and 33 show the same cross-sections as FIG. 9.

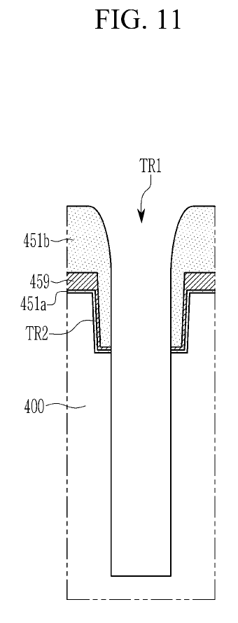

Referring to FIGS. 10 and 11, first, the first trench TR1 may be formed in the substrate 400. The second trench TR2 may be first formed before the process of forming the first trench TR1, and a 1a-th PD isolation pattern 451a, the third PD isolation pattern 459 and a 1b-th PD isolation pattern 451b may be sequentially stacked on the second trench TR2. Afterwards, the first trench TR1 may be formed.

As shown in FIGS. 10 and 11, the 1a-th PD isolation pattern 451a may be formed along a surface of the second trench TR2 and a surface of the substrate 400, and its thickness may be 3 nm to 5 nm. The 1a-th PD isolation pattern 451a may improve the interface characteristics between the third PD isolation pattern 459 and the substrate 400. The 1a-th PD isolation pattern 451a may include silicon oxide.

The third PD isolation pattern 459 may be formed along the formed 1a-th PD isolation pattern 451a, and may be formed in a thickness of 5 nm to 8 nm. The third PD isolation pattern 459 may include silicon nitride.

The 1b-th PD isolation pattern 451b may be formed on the third PD isolation pattern 459. The 1a-th PD isolation pattern 451a and the 1b-th PD isolation pattern 451b may include silicon oxide.

Afterwards, as shown in FIGS. 10 and 11, the first trench TR1 may be formed by etching the substrate 400, the 1a-th PD isolation pattern 451a, the third PD isolation pattern 459 and the 1b-th PD isolation pattern 451b.

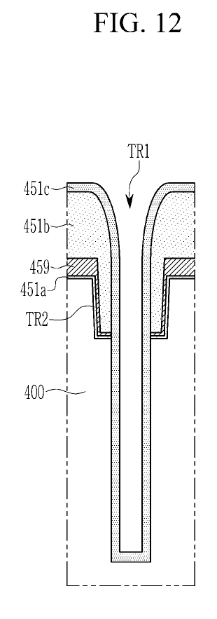

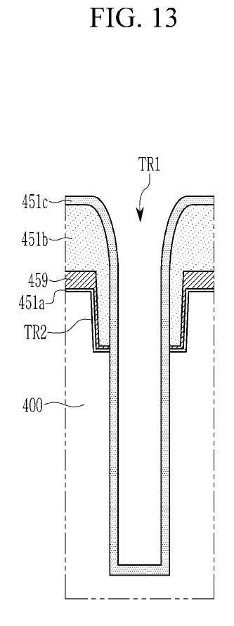

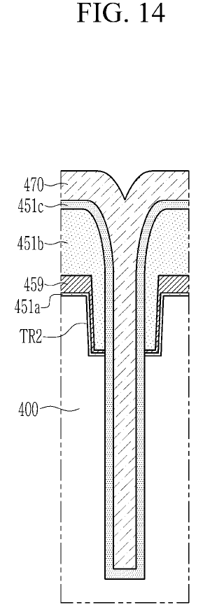

Subsequently, referring to FIGS. 12 and 13, a 1c-th PD isolation pattern 451c may be formed within the first trench TR1. The 1c-th PD isolation pattern 451c may be formed along the side wall of the first trench TR1, and may also be formed on a side surface and an upper surface of the 1b-th PD isolation pattern 451b. The 1c-th PD isolation pattern 451c may include silicon oxide. That is, the 1b-th PD isolation pattern 451b and the 1c-th PD isolation pattern 451c may include the same material, and in this case, a boundary between the 1b-th PD isolation pattern 451b and the 1c-th PD isolation pattern 451c may not be visible. However, in the drawings of the present manufacturing method according to one or more example embodiments, for convenience of description, boundaries of materials formed at respective steps are distinguishably illustrated although they include the same material.

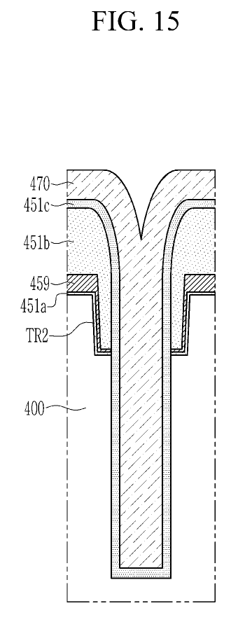

Subsequently, referring to FIGS. 14 and 15, the first trench TR1 is filled with a sacrificial layer 470. The sacrificial layer 470 may also be formed inside of the first trench TR1 and on the upper surface of the 1c-th PD isolation pattern 451c. The sacrificial layer 470 may include carbon. For example, the sacrificial layer 470 may be at least one of combinations of C₂H₂, C₃H₆, C₃H₆, and B₂H₆, but is not limited thereto.

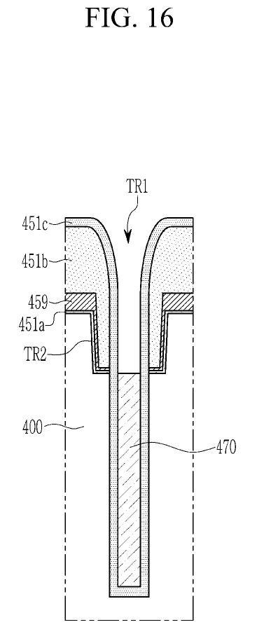

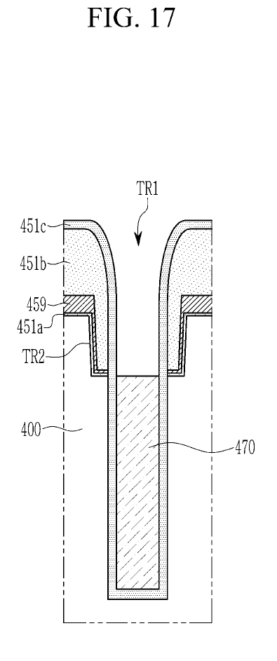

Subsequently, referring to FIGS. 16 and 17, the sacrificial layer 470 may be etched. At this time, the etching may be performed until the sacrificial layer 470 provided above the first trench TR1 is removed. As will be described below, a region where the sacrificial layer 470 remaining at the present step is provided may be a region where the second PD isolation pattern 453 and the void 457 are formed afterwards. That is, at the present step, a remaining sacrificial layer except for the sacrificial layer 470 provided within the first trench TR1 may be removed.

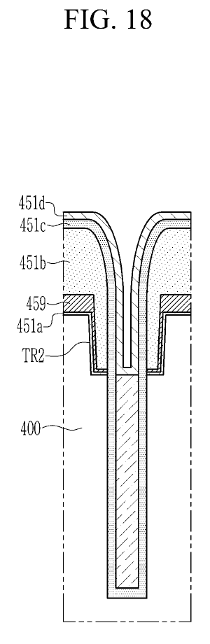

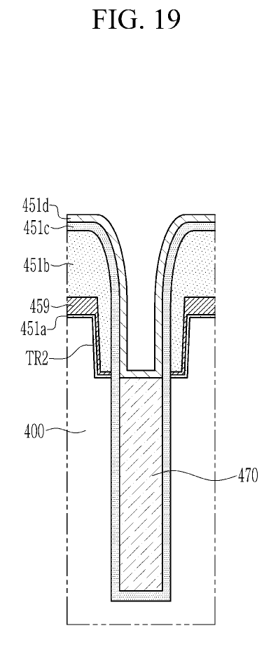

Subsequently, referring to FIGS. 18 and 19, a 1d-th PD isolation pattern 451d may be formed on the sacrificial layer 470 and the 1c-th PD isolation pattern 451c. The 1d-th PD isolation pattern 451d may cover an upper surface of the first trench TR1. The 1d-th PD isolation pattern 451d may include silicon oxide. Accordingly, it may include the same material as the 1c-th PD isolation pattern 451c, the 1b-th PD isolation pattern 451b, and the 1a-th PD isolation pattern 451a formed at the previous step, and in this case, the boundary between the 1d-th PD isolation pattern 451d, the 1c-th PD isolation pattern 451c, the 1b-th PD isolation pattern 451b, and the 1a-th PD isolation pattern 451a may not be visible. However, in the drawings of the present manufacturing method according to one or more example embodiments, for convenience of description, boundaries of materials formed at respective steps are distinguishably illustrated although they include the same material. However, in one or more example embodiments, the 1d-th PD isolation pattern 451d may include a material different from the 1c-th PD isolation pattern 451c. In this case, the boundary between the 1d-th PD isolation pattern 451d and the 1c-th PD isolation pattern 451c may be visible.

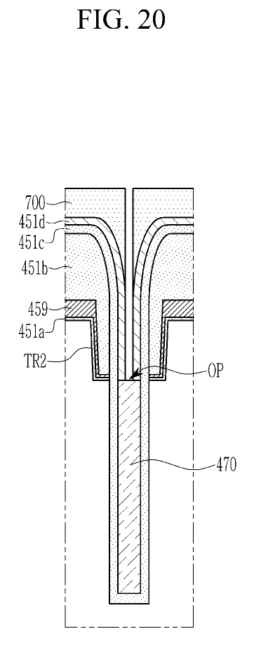

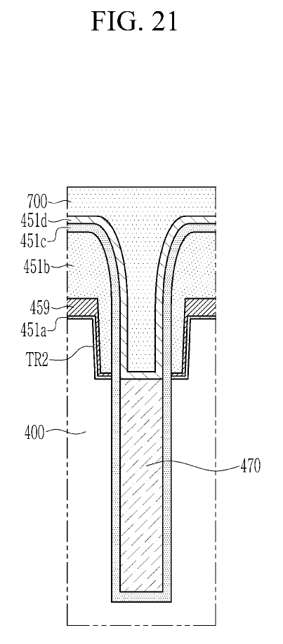

Subsequently, referring to FIGS. 20 and 21, a part of the 1d-th PD isolation pattern 451d may be etched by using a mask 700, so that an open portion OP may be formed in a partial region of the 1d-th PD isolation pattern 451d. In one or more example embodiments, in the cross-section of FIG. 20, the open portion OP is formed in the 1d-th PD isolation pattern 451d. Because the 1d-th PD isolation pattern 451d is open in the cross-section of FIG. 20, the 1d-th PD isolation pattern 451d may not be open in the cross-section of FIG. 21. However, this is merely an example, and in one or more example embodiments, an open portion may be formed in the 1d-th PD isolation pattern 451d in the cross-section of FIG. 21, and an open portion may not be formed in the 1d-th PD isolation pattern 451d in the cross-section of FIG. 20.

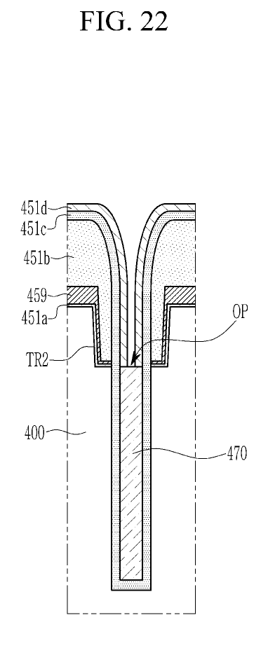

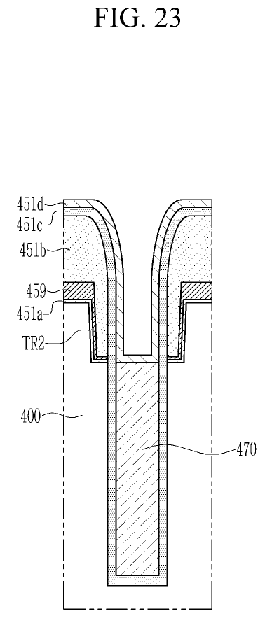

Subsequently, referring to FIGS. 22 and 23, the mask 700 may be removed. Referring to FIGS. 22 and 23, an upper surface of the sacrificial layer 470 may be partially exposed according to forming of the open portion OP.

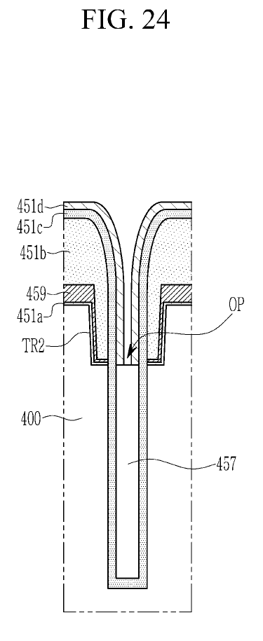

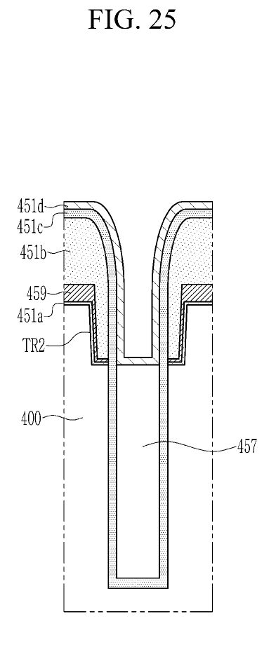

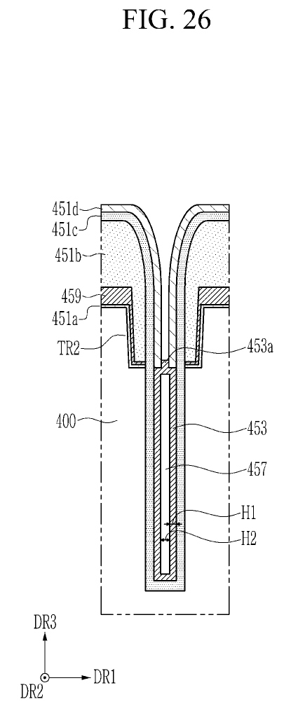

Subsequently, referring to FIGS. 24 and 25, the sacrificial layer 470 may be removed. At this time, the removal of the sacrificial layer 470 may be performed by using the open portion OP. That is, because the sacrificial layer 470 is exposed in the region where the open portion OP is provided, the sacrificial layer 470 may be removed by injecting an etchant into corresponding region. Referring to FIGS. 24 and 25, by removing the sacrificial layer 470, the void 457 may be formed in the region where the sacrificial layer 470 was provided.

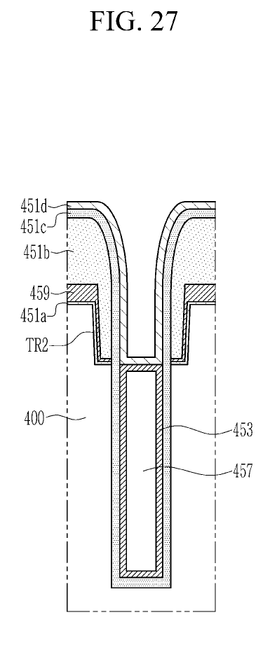

Subsequently, referring to FIGS. 26 and 27, the second PD isolation pattern 453 may be formed along an inner wall of the void 457. Through the open portion OP of the 1d-th PD isolation pattern 451d formed at the previous step, the second PD isolation pattern 453 may be formed inside the void 457. The detailed description on the second PD isolation pattern 453 is the same as described above, and a duplicate description has been omitted. That is, the second PD isolation pattern 453 may include a crystalline semiconductor material, for example, polycrystalline silicon. For example, the second PD isolation pattern 453 may further include a dopant, and the dopant may include impurities of the first conductivity type or impurities of the second conductivity type. A thickness of the second PD isolation pattern 453 formed at the present step in the first direction DR1 may be 4 nm to 8 nm. The second PD isolation pattern 453 may be formed in a uniform thickness within the first trench TR1. The meaning of the uniform thickness may mean that a thickness difference between a thickest portion and a thinnest portion of the second PD isolation pattern 453 is 10 % or less.

As shown in FIGS. 26 and 27, the second PD isolation pattern 453 may be formed along the inner wall of the void 457. A majority of the void 457 may remain as an empty space. As described above, within the first trench TR1, an area of a portion occupied by the void 457 may be wider than the area of a portion occupied by the second PD isolation pattern 453. That is, as shown in FIG. 26, the width H2 in of the void 457 in the first direction DR1 may be greater than the thickness H1 of the second PD isolation pattern 453 in the first direction DR1. Specifically, the width H2 in of the void 457 in the first direction DR1 may be 3 times to 40 times of the thickness H1 of the second PD isolation pattern 453 in the first direction DR1. That is, most of the first trench TR1 may be empty.

Referring to FIG. 26, the protruding portion 453a of the second PD isolation pattern 453 may be provided in the region where the open portion OP was provided at the previous step. This is a structure that can be derived during the process of forming the second PD isolation pattern 453 through the open portion OP. That is, when the second PD isolation pattern 453 is deposited even after the open portion OP is blocked by the second PD isolation pattern 453 during the process of forming the second PD isolation pattern 453, the second PD isolation pattern 453 may protrude, to constitute the protruding portion 453a.

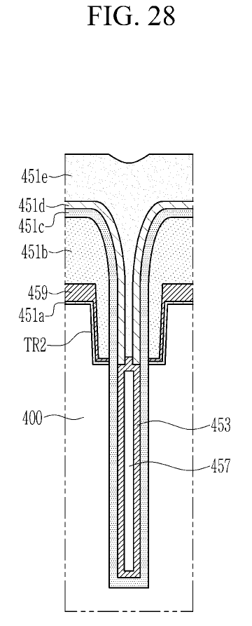

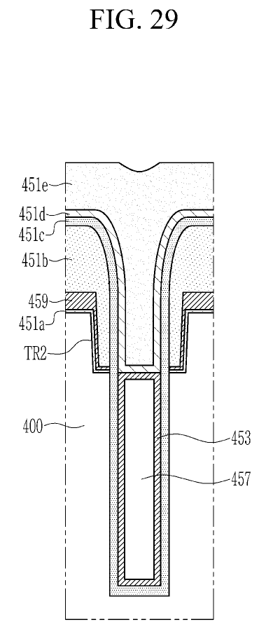

Subsequently, referring to FIGS. 28 and 29, a 1e-th PD isolation pattern 451e may be formed. The 1e-th PD isolation pattern 451e may fill the first trench TR1 that was not filled the previous step. The 1e-th PD isolation pattern 451e may include silicon oxide. That is, the 1e-th PD isolation pattern 451e may include the same material as the 1d-th PD isolation pattern 451d, the 1c-th PD isolation pattern 451c, the 1b-th PD isolation pattern 451b, and the 1a-th PD isolation pattern 451a. In this case, the boundary between the 1e-th PD isolation pattern 451e and the 1d-th PD isolation pattern 451d, the 1c-th PD isolation pattern 451c, the 1b-th PD isolation pattern 451b, and the 1a-th PD isolation pattern 451a may not be visible. That is, when the 1e-th PD isolation pattern 451e, the 1d-th PD isolation pattern 451d, the 1c-th PD isolation pattern 451c, the 1b-th PD isolation pattern 451b, and the 1a-th PD isolation pattern 451a includes the same material so that the boundary is not visible, the 1e-th PD isolation pattern 451e, the 1d-th PD isolation pattern 451d, the 1c-th PD isolation pattern 451c, the 1b-th PD isolation pattern 451b, and the 1a-th PD isolation pattern 451a may be visible in the same shape as the first PD isolation pattern 451 illustrated in FIGS. 6, 7, 8 and 9.

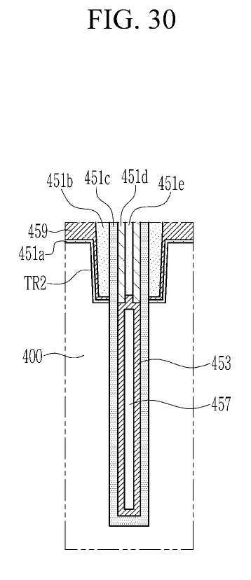

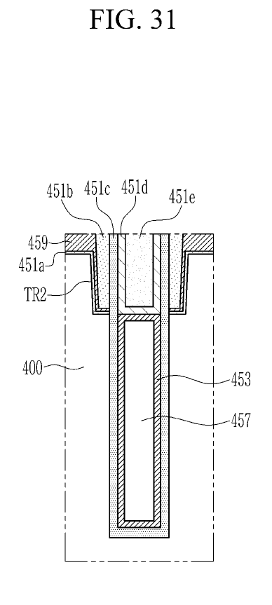

Subsequently, referring to FIGS. 30 and 31, planarization may be performed by performing a Chemical Mechanical Planarization (CMP) process on one surface. As shown in FIGS. 30 and 31, through the CMP process of the present step, a flat upper surface may be obtained. The CMP process may be performed by using the third PD isolation pattern 459 as an etch stop layer. That is, at the present step, the PD isolation pattern provided on the upper surface of the third PD isolation pattern 459 may be removed. Although FIGS. 30 and 31 illustrate the boundary between the 1e-th PD isolation pattern 451e, the 1d-th PD isolation pattern 451d, the 1c-th PD isolation pattern 451c, the 1b-th PD isolation pattern 451b, and the 1a-th PD isolation pattern 451a, when the 1e-th PD isolation pattern 451e, the 1d-th PD isolation pattern 451d, the 1c-th PD isolation pattern 451c, the 1b-th PD isolation pattern 451b, and the 1a-th PD isolation pattern 451a include the same material, the boundary may not be distinguished but may be visible as a single pattern.

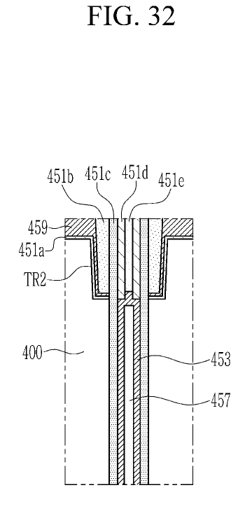

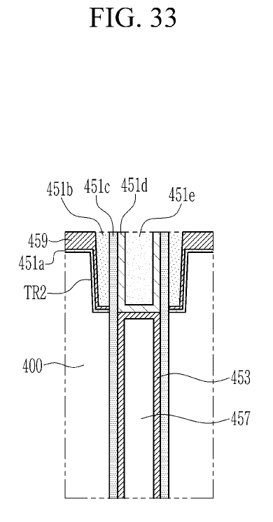

Subsequently, referring to FIGS. 32 and 33, the CMP process may be performed on a surface on which the CMP process was not performed at the previous step. Through this, as shown in FIGS. 32 and 33, the second PD isolation pattern 453, which is connected at the bottom surface, may be separated, to expose the void 457.

Afterwards, the insulation structure and lens illustrated in FIGS. 6 and 7 may be formed on the surface on which the CMP process is performed at the present step, to form the image sensor.

Hereinafter, one or more modified example embodiments will be described with reference to various drawings.

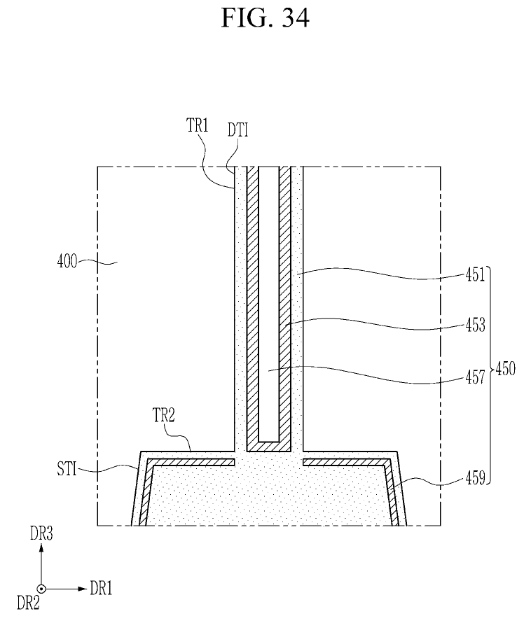

FIG. 34 shows the same cross-section as FIG. 8, with respect to one or more example embodiments. Referring to FIG. 34, an image sensor according to one or more example embodiments is the same as FIG. 8, except that the second PD isolation pattern 453 does not include a protruding portion. A duplicate detailed description of the same configuration has been omitted. The image sensor according to FIG. 34 may be formed by adjusting the degree of deposition of the second PD isolation pattern 453 in the previous manufacturing process of FIG. 26. That is, when the deposition is stopped at the moment when the open portion OP is blocked by the second PD isolation pattern 453, as shown in FIG. 34, the second PD isolation pattern 453, that does not include a protruding portion, may be formed.

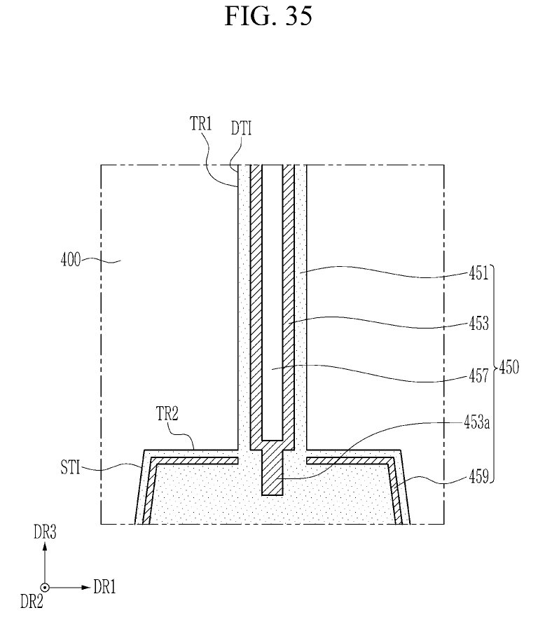

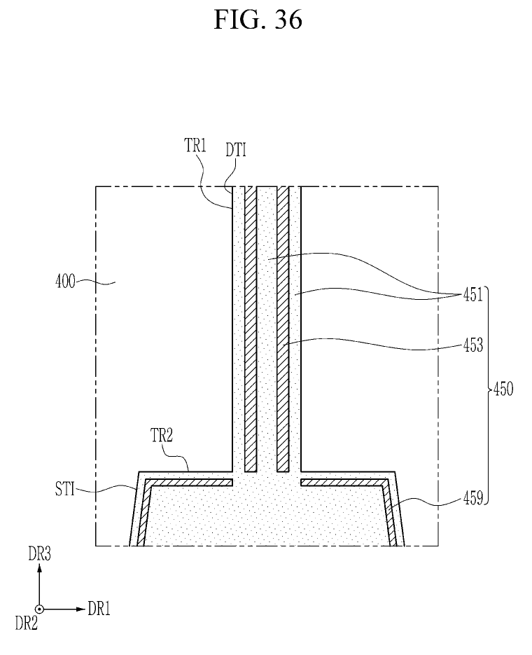

FIG. 35 shows the same cross-section as FIG. 8, with respect to one or more example embodiments. Referring to FIG. 34, an image sensor according to one or more example embodiments is the same as the one or more example embodiments of FIG. 8, except that the protruding portion 453a of the second PD isolation pattern 453 protrudes in the direction of the second trench TR2. A duplicate detailed description of the same configuration has been omitted. The image sensor according to FIG. 34 may be formed by adjusting the degree of deposition of the second PD isolation pattern 453 in the previous manufacturing process of FIG. 26. That is, when deposition is continued even after the open portion OP is blocked by the second PD isolation pattern 453, as shown in FIG. 35, the second PD isolation pattern 453, in which the protruding portion 453a protrudes in the direction toward the second trench TR2, may be formed.

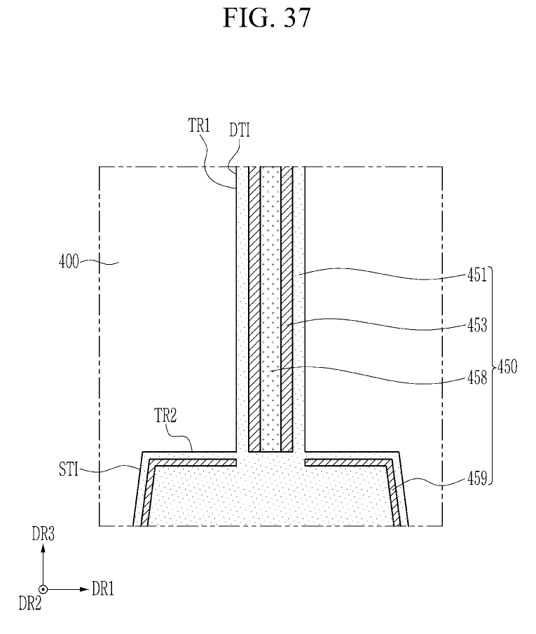

FIG. 36 shows the same cross-section as FIG. 8, with respect to one or more example embodiments. Referring to FIG. 36, an image sensor according to one or more example embodiments is the same as FIG. 8, except that the second PD isolation pattern 453 is separated and the first PD isolation pattern 451 is provided in the region where the void 457 was provided. A duplicate detailed description of the same configuration has been omitted. That is, in the case of the one or more example embodiments of FIG. 36, the second PD isolation pattern 453 may be separated, and the first PD isolation pattern 451 may be provided between the second PD isolation pattern 453. The void 457 of the previous one or more example embodiments may be filled with the first PD isolation pattern 451, and even in this case, the area occupied by the second PD isolation pattern 453, in the PD isolation pattern 450, is small. Accordingly, similar to the one or more example embodiments of FIG. 8, light absorption and sensitivity deterioration problems due to polycrystalline silicon included in the second PD isolation pattern 453 may be prevented.

FIG. 37 shows the same cross-section as FIG. 36, with respect to one or more example embodiments. Referring to FIG. 37, an image sensor according to one or more example embodiments is the same as FIG. 36, except that a space between the second PD isolation pattern 453 is filled with a fourth PD isolation pattern 458. A duplicate detailed description of the same configuration has been omitted. The fourth PD isolation pattern 458 may include a metal. Alternatively, the fourth PD isolation pattern 458 may include an insulation layer. That is, in the case of FIG. 36, the first PD isolation pattern 451 including an insulating material was provided between the second PD isolation pattern 453, but in the one or more example embodiments of FIG. 37, the fourth PD isolation pattern 458 including a metal between the second PD isolation pattern 453 may be provided. Even in this case, the area occupied by the second PD isolation pattern 453 in the PD isolation pattern 450 is small. Accordingly, similar to the one or more example embodiments of FIG. 8, the sensitivity deterioration problem due to polycrystalline silicon included in the second PD isolation pattern 453 may be prevented. Even when the fourth PD isolation pattern 458 includes an insulation layer, the area occupied by the second PD isolation pattern 453 in the PD isolation pattern 450 decreases, and the sensitivity deterioration problem due to polycrystalline silicon included in the second PD isolation pattern 453 may be prevented.

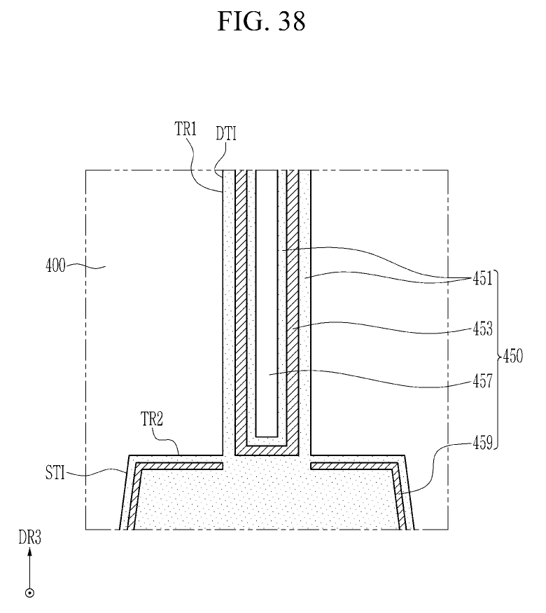

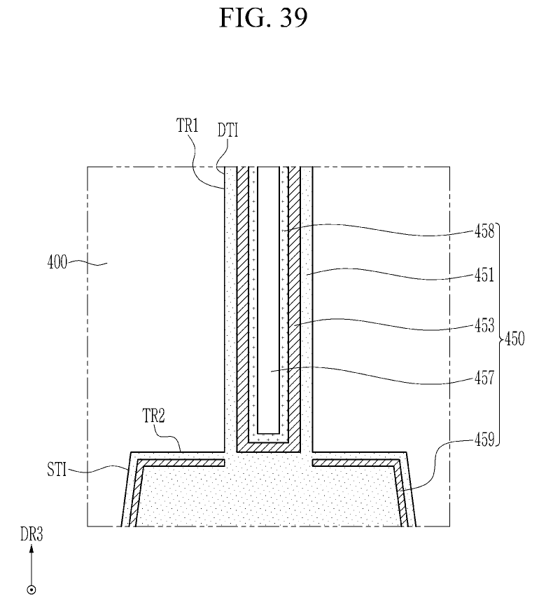

FIG. 38 shows the same cross-section as FIG. 9, with respect to one or more example embodiments. Referring to FIG. 38, in an image sensor according to one or more example embodiments, both the first PD isolation pattern 451 and the void 457 may be provided in the space between the second PD isolation pattern 453. That is, the cross-section of FIG. 38 illustrates an image sensor according to the one or more example embodiments of FIG. 36, another cross-section, that is, the same cross-section as FIG. 9 in the B-B’ direction. An image sensor according to one or more example embodiments of FIG. 36 may be a cross-section in the A-A’ direction, and FIG. 38 may be a cross-section in the B-B’ direction. Referring to FIG. 38, both the first PD isolation pattern 451 and the void 457 may be provided in the space between the second PD isolation pattern 453. This is because, in the cross-section of FIG. 36, when the first PD isolation pattern 451 is formed into the space inside the second PD isolation pattern 453, the first PD isolation pattern 451 may be simultaneously formed in the integrally connected entire second PD isolation pattern 453. At this time, because the width of the cross-section in the B-B’ direction is wider than that of the cross-section in the A-A’ direction, the void 457 may not completely filled with the first PD isolation pattern 451 in the cross-section in the B-B’ direction. Accordingly, as shown in FIG. 38, in the cross-section in the B-B’ direction, both the first PD isolation pattern 451 and the void 457 may be provided in the space between the second PD isolation pattern 453. However, this is merely an example, and in the cross-section in the B-B’ direction, the space between the second PD isolation pattern 453 may be entirely filled with the first PD isolation pattern 451 and a void may not be provided.

FIG. 39 shows the same cross-section as FIG. 38, with respect to one or more example embodiments. Referring to FIG. 39, an image sensor according to one or more example embodiments is the same as FIG. 38, except that the space between the second PD isolation pattern 453 is filled with the fourth PD isolation pattern 458. A duplicate detailed description of the same configuration has been omitted. The cross-section of FIG. 39 illustrates an image sensor according to the one or more example embodiments of FIG. 37, another cross-section, that is, the same cross-section as FIG. 9 in the B-B’ direction. An image sensor according to the same one or more example embodiments of FIG. 37 may be a cross-section in the A-A’ direction, and FIG. 39 may be a cross-section in the B-B’ direction. Accordingly, as shown in FIG. 39, in the cross-section in the B-B’ direction, both the fourth PD isolation pattern 458 and the void 457 may be provided in the space between the second PD isolation pattern 453.

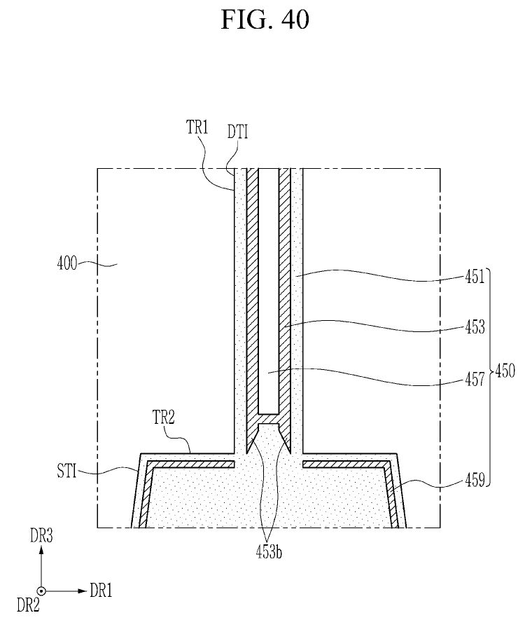

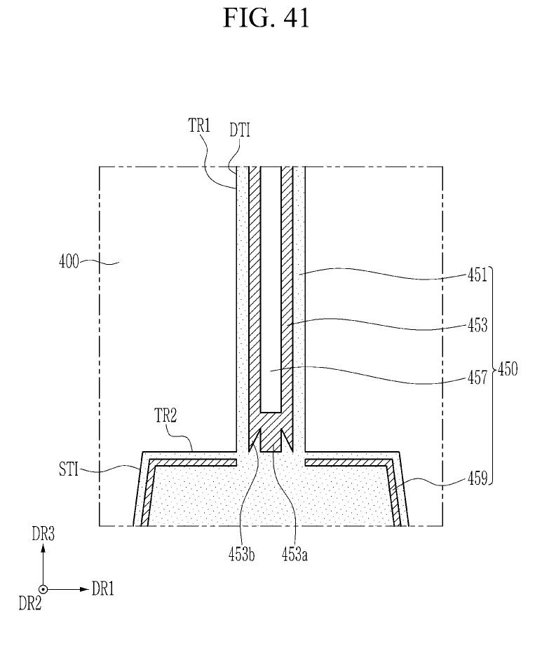

FIG. 40 illustrates the same region as FIG. 34, with respect to one or more example embodiments. Referring to FIG. 40, an image sensor according to one or more example embodiments is the same as the one or more example embodiments of FIG. 34, except that the second PD isolation pattern 453 includes an edge portion 453b provided on the edge. A duplicate detailed description of the same configuration has been omitted. The edge portion 453b in FIG. 40 is a structure that can be derived when the upper surface of the sacrificial layer 470 is not uniformly etched in the process of FIGS. 16 and 17 during the manufacturing method. That is, in the case of FIGS. 16 and 17, although it is illustrated that the upper surface of the sacrificial layer 470 is etched to be flat, the upper surface of the sacrificial layer 470 may have a concave shape according to the etching profile during the etching process, and when the sacrificial layer 470 having such a concave upper surface is removed and the second PD isolation pattern 453 is formed in the space, the edge portion 453b illustrated in FIG. 40 may be formed on the edge.

FIG. 41 illustrates the same region as FIG. 40, with respect to one or more example embodiments. Referring to FIG. 41, an image sensor according to one or more example embodiments is the same as the one or more example embodiments of FIG. 40, except that the second PD isolation pattern 453 further includes the protruding portion 453a. A duplicate detailed description of the same configuration has been omitted. That is, the one or more example embodiments of FIG. 41 may include both the edge portion 453b and the protruding portion 453a.

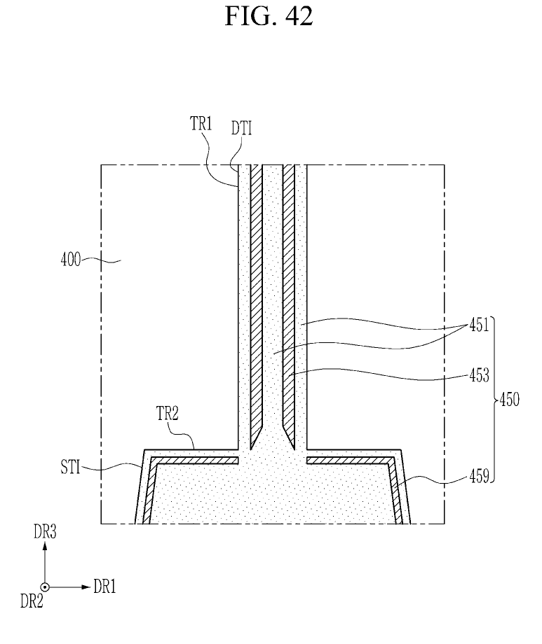

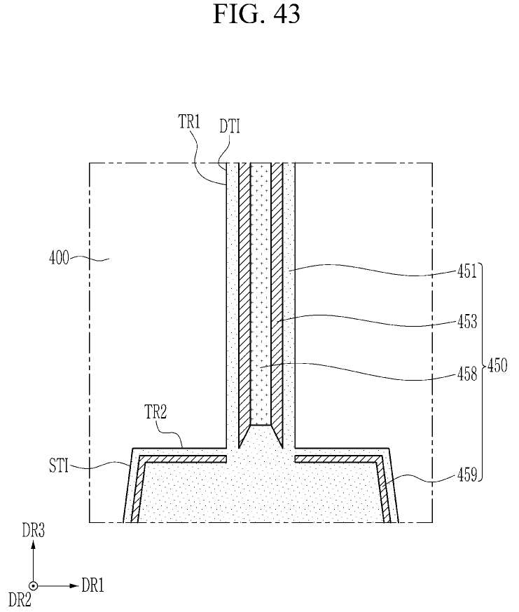

FIG. 42 illustrates the same region as FIG. 40, with respect to one or more example embodiments. The one or more example embodiments of FIG. 42 is the same as FIG. 40 except that the second PD isolation pattern 453 is separated and the first PD isolation pattern 451 is provided in the region where the void 457 was provided and that an edge of the second PD isolation pattern 453 has an inclined surface. A duplicate detailed description of the same configuration has been omitted. The inclined surface shown in FIG. 42 may be a structure that is derived when the sacrificial layer 470 is not etched to be flat while etching the sacrificial layer 470, as described above. That is, in the case of the one or more example embodiments of FIG. 42, the second PD isolation pattern 453 may be separated, and the first PD isolation pattern 451 may be provided between the second PD isolation pattern 453.

FIG. 43 illustrates the same region as FIG. 42, with respect to one or more example embodiments. An image sensor according to the one or more example embodiments of FIG. 43 is the same as FIG. 42, except that the space between the second PD isolation pattern 453 is filled with the fourth PD isolation pattern 458. A duplicate detailed description of the same configuration has been omitted. The fourth PD isolation pattern 458 may include a metal or insulation layer. That is, in the case of FIG. 42, the first PD isolation pattern 451 including an insulating material was provided between the second PD isolation pattern 453, but in the one or more example embodiments of FIG. 43, the fourth PD isolation pattern 458 including a metal or an insulation layer may be provided between the second PD isolation pattern 453.

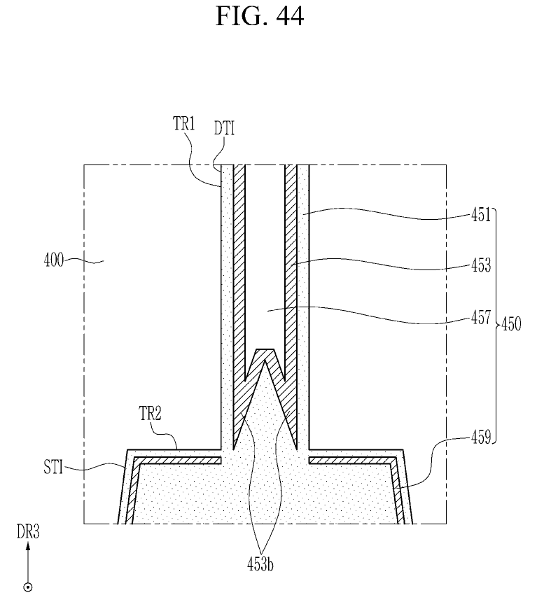

FIG. 44 shows another cross-section with respect to the one or more example embodiments of FIG. 40. That is, in the image sensor according to one or more example embodiments of FIG. 40 may be a cross-section in the A-A’ direction (the same cross-section as FIG. 8), and FIG. 44 may be a cross-section in the B-B’ direction (the same cross-section as FIG. 9). Referring to FIG. 44, the cross-section of FIG. 44 may also include the second PD isolation pattern 453 where the edge portion 453b is provided on the edge. As described with reference to FIG. 40, when the upper surface of the sacrificial layer 470 is formed to be concave during the manufacturing process, the edge portion 453b as shown in FIG. 44 may be formed on the edge.

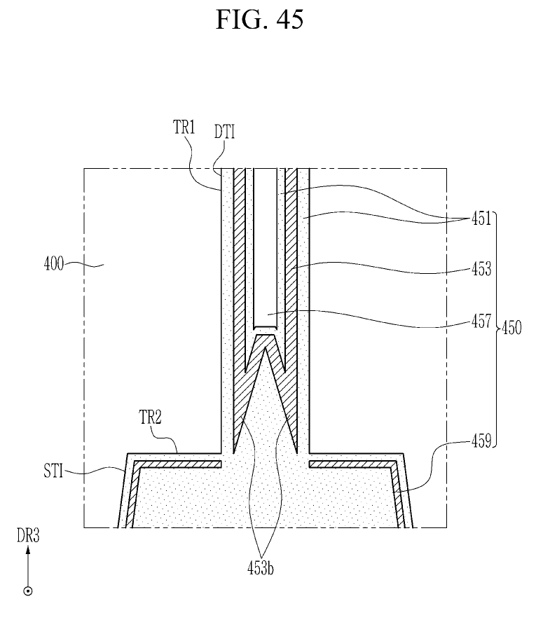

FIG. 45 shows another cross-section with respect to the one or more example embodiments of FIG. 42. That is, in the image sensor according to one or more example embodiments of FIG. 42 may be a cross-section in the A-A’ direction (same cross-section as FIG. 8), and FIG. 45 may be a cross-section in the B-B’ direction (same cross-section as FIG. 9). Referring to FIG. 45, both the first PD isolation pattern 451 and the void 457 may be provided in the space between the second PD isolation pattern 453. This is because, the width of the cross-section in the B-B’ direction is wider than that of the cross-section in the A-A’ direction, and thus the void 457 may not be completely filled with the first PD isolation pattern 451 in the cross-section in the B-B’ direction.

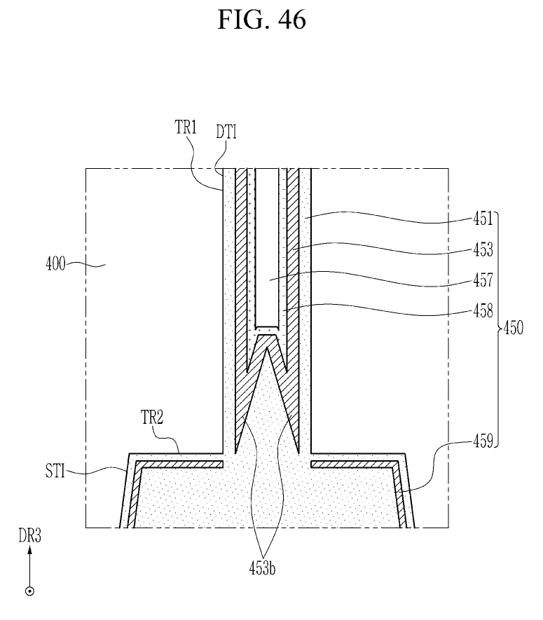

FIG. 46 shows another cross-section with respect to the one or more example embodiments of FIG. 43. That is, in the image sensor according to one or more example embodiments of FIG. 43 may be a cross-section in the A-A’ direction (same cross-section as FIG. 8), and FIG. 46 may be a cross-section in the B-B’ direction (same cross-section as FIG. 9). Referring to FIG. 46, both the fourth PD isolation pattern 458 and the void 457 may be provided in the space between the second PD isolation pattern 453. This is because, the width in the cross-section in the B-B’ direction is wider than that of the cross-section in the A-A’ direction, and thus the void 457 may not be completely filled with the fourth PD isolation pattern 458 in the cross-section in the B-B’ direction. The fourth PD isolation pattern 458 may include a metal or insulation layer.

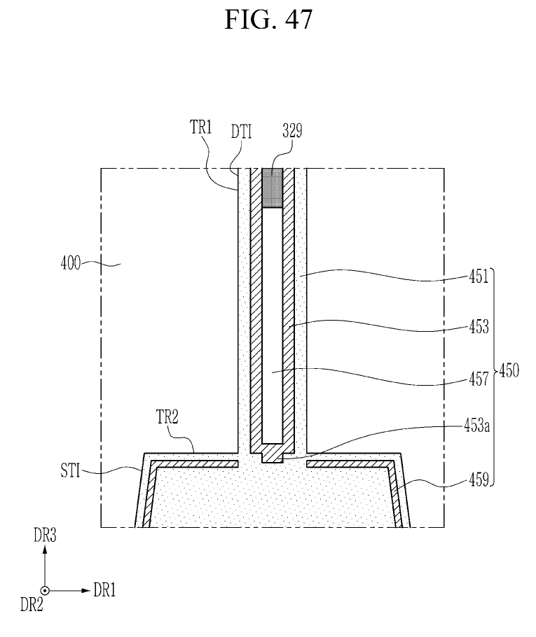

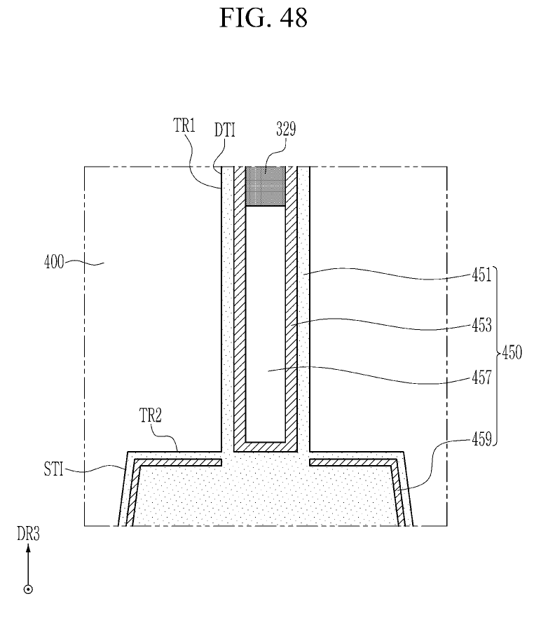

FIG. 47 illustrates the same cross-section as FIG. 8, and FIG, with respect to one or more example embodiments. 48 illustrates the same cross-section as FIG. 9. Referring to FIGS. 47 and 48, an image sensor according to one or more example embodiments is the same as the one or more example embodiments of FIGS. 8 and 9, except that a part of the insulation structure 329 is provided within the void 457. A duplicate detailed description of the same configuration has been omitted. That is, in the process after FIGS. 32 and 33 during the manufacturing process, the insulation structure 329 may be formed in a first surface of the substrate 400, and at this time, the void 457 is exposed, such that some of the material of the insulation structure 329 may also be formed within the void 457 during the manufacturing process. However, depending on the material characteristic of the insulation structure 329, it may not be formed within the void 457. When some of the material of the insulation structure 329 is formed within the void 457, the shape may be similar to that illustrated in FIGS. 47 and 48, or may be formed along the side wall in a shape similar to the second PD isolation pattern 453.

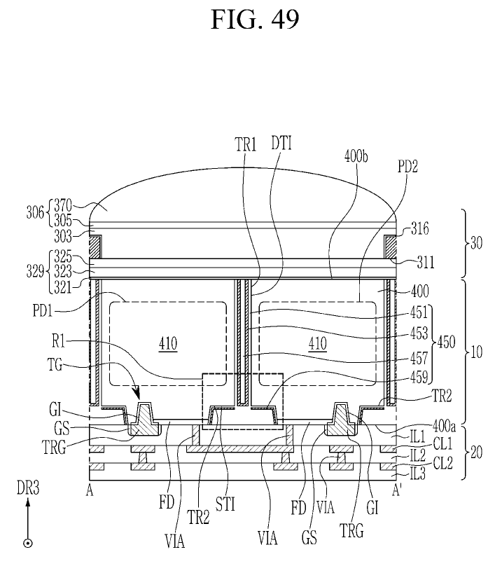

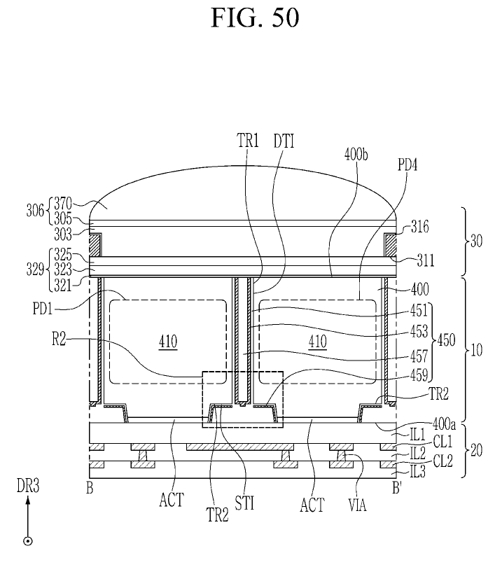

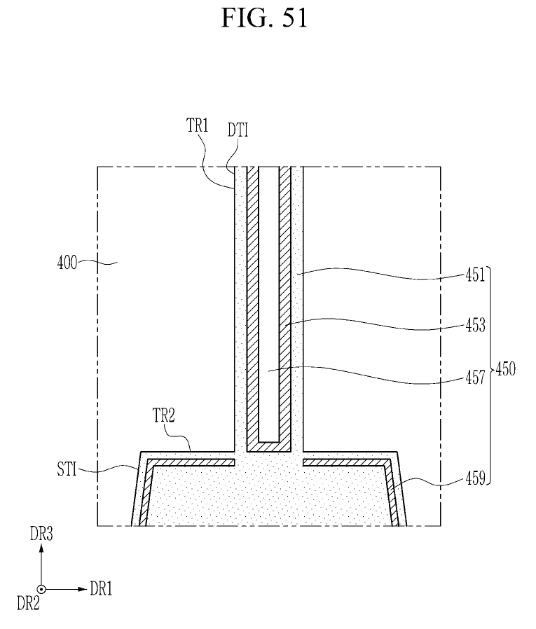

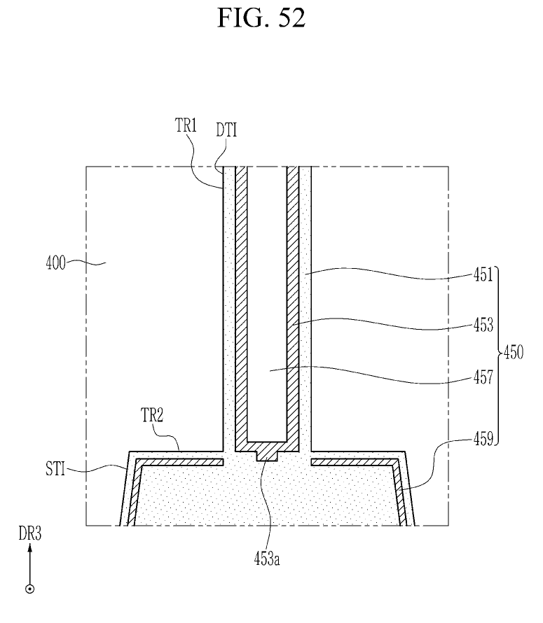

Hereinafter, one or more example embodiments will be described with reference to the drawings. FIG. 49 shows the same cross-section as FIG. 6, with respect to one or more example embodiments, and FIG. 50 show the same cross-section as FIG. 7, with respect to one or more example embodiments. FIG. 51 is an enlarged view of the portion indicated by R1 in FIGS. 49, and 52 is an enlarged view of the portion indicated by R2 in FIG. 50.

In the one or more example embodiments of FIGS. 6, 7, 8 and 9, a protruding portion of the second PD isolation pattern 453 was provided in FIG. 8, which is a cross-section in the A-A’ direction, and the protruding portion of the second PD isolation pattern 453 was not provided in FIG. 9, which is a cross-section in the B-B’ direction, but in the one or more example embodiments of FIGS. 49, 50, 51 and 52, the protruding portion of the second PD isolation pattern 453 may not be provided in FIGS. 49 and 51, which are cross-sections in the A-A’ direction, and the protruding portion 453a of the second PD isolation pattern 453 may be provided in FIGS. 50 and 52, which are cross-sections in the B-B’ direction.

That is, FIGS. 49 and 51 are FIG. 6 and the same as the one or more example embodiments of FIG. 8, except that the second PD isolation pattern 453 does not include a protruding portion. A duplicate detailed description of the same configuration has been omitted. In the same way, FIGS. 50 and 52 are the same as the one or more example embodiments of FIGS. 7 and 9, except that the second PD isolation pattern 453 includes the protruding portion 453a. A duplicate detailed description of the same configuration has been omitted. That is, FIGS. 49, 50, 51 and 52 may be a structure manufactured by not forming the open portion OP in the 1d-th PD isolation pattern 451d in the cross-section in the A-A’ direction, but forming the open portion OP in the 1d-th PD isolation pattern 451d in the cross-section in the B-B’ direction, during the manufacturing process.

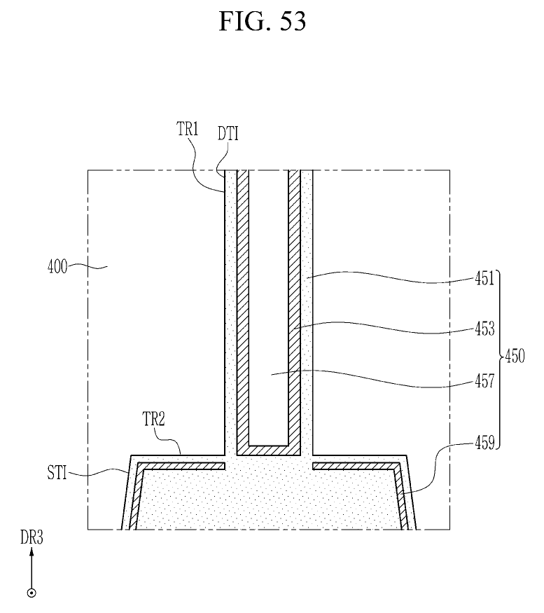

FIG. 53 shows the same cross-section as FIG. 52, with respect to one or more example embodiments. Referring to FIG. 53, an image sensor according to one or more example embodiments is the same as FIG. 52, except that the second PD isolation pattern 453 does not include a protruding portion. A duplicate detailed description of the same configuration has been omitted. Such a structure may be derived by adjusting the degree of deposition of the second PD isolation pattern 453 during the manufacturing process. When the deposition is stopped at the moment when the open portion OP is blocked by the second PD isolation pattern 453, as shown in FIG. 53, the second PD isolation pattern 453, that does not include a protruding portion, may be formed.

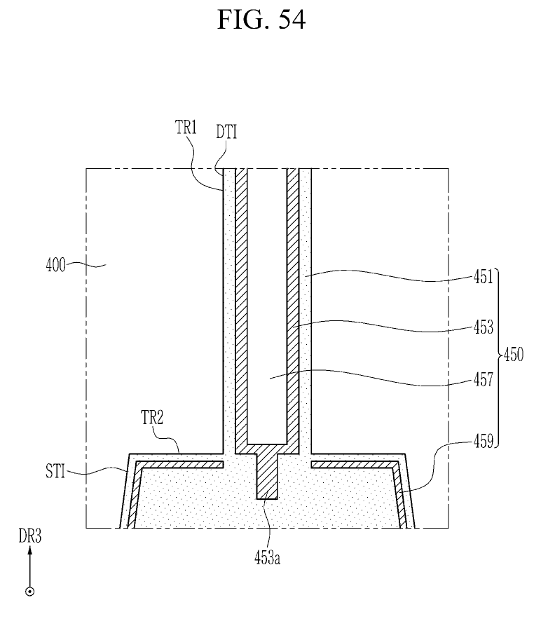

FIG. 54 shows the same cross-section as FIG. 52, with respect to one or more example embodiments. Referring to FIG. 54, an image sensor according to one or more example embodiments is the same as the one or more example embodiments of FIG. 52, except that the protruding portion 453a of the second PD isolation pattern 453 protrudes toward the region of the second trench TR2. A duplicate detailed description of the same configuration has been omitted. The image sensor according to FIG. 54 may be formed by adjusting the degree of deposition of the second PD isolation pattern 453 during the manufacturing process. That is, when deposition is continued even after the open portion OP is blocked by the second PD isolation pattern 453, as shown in FIG. 54, the second PD isolation pattern 453 in which the protruding portion 453a protrudes in the direction toward the second trench TR2 may be formed.

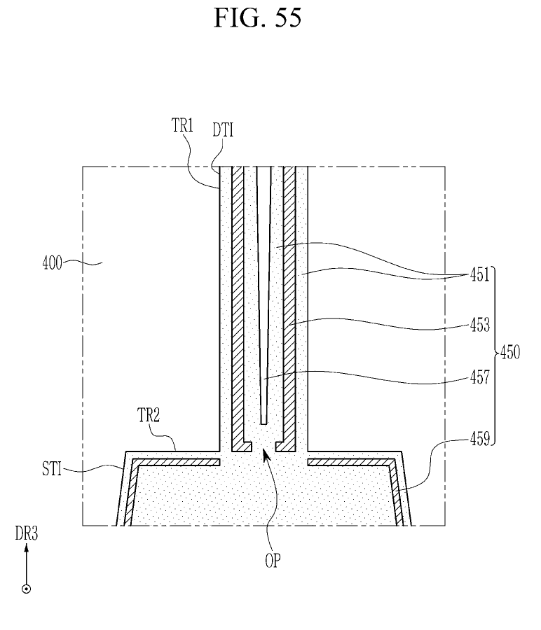

FIG. 55 shows the same cross-section as FIG. 52, with respect to one or more example embodiments. Referring to FIG. 36, an image sensor according to one or more example embodiments is the same as FIG. 52, except that the second PD isolation pattern 453 is separated, and the void 457 and the first PD isolation pattern 451 are provided in the region between the second PD isolation pattern 453. A duplicate detailed description of the same configuration has been omitted. That is, in the case of the one or more example embodiments of FIG. 52, the upper surface of the second PD isolation pattern 453 may not be sealed to include an open portion, and through such an open portion, the first PD isolation pattern 451 may be formed in the interior space of the second PD isolation pattern 453. The first PD isolation pattern 451 may not completely fill the interior space of the second PD isolation pattern 453, and the void 457 may remain in a certain region.

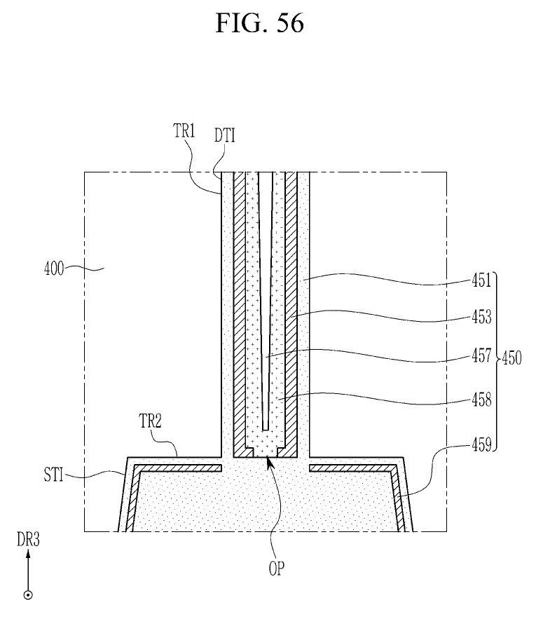

FIG. 56 illustrates the same region as FIG. 55, with respect to one or more example embodiments. Referring to FIG. 56, an image sensor according to one or more example embodiments is the same as FIG. 55, except that the space between the second PD isolation pattern 453 is filled with the fourth PD isolation pattern 458 instead of the first PD isolation pattern 451. A duplicate detailed description of the same configuration has been omitted. The fourth PD isolation pattern 458 may include a metal or insulation layer.

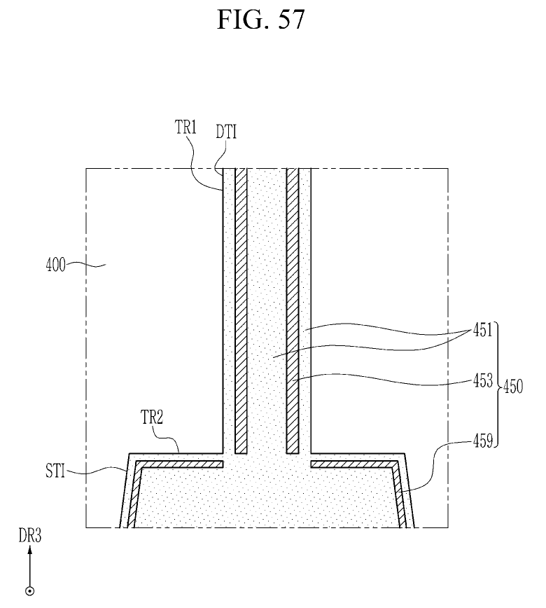

FIG. 57 shows the same cross-section as FIG. 52, with respect to one or more example embodiments. Referring to FIG. 57, an image sensor according to one or more example embodiments is the same as FIG. 52, except that the second PD isolation pattern 453 is separated, and the first PD isolation pattern 451 are provided in the region between the second PD isolation pattern 453. A duplicate detailed description of the same configuration has been omitted. When compared with FIG. 55, in one or more example embodiments, the space between the second PD isolation pattern 453 may be completely filled with the first PD isolation pattern 451 and a void may not be provided.

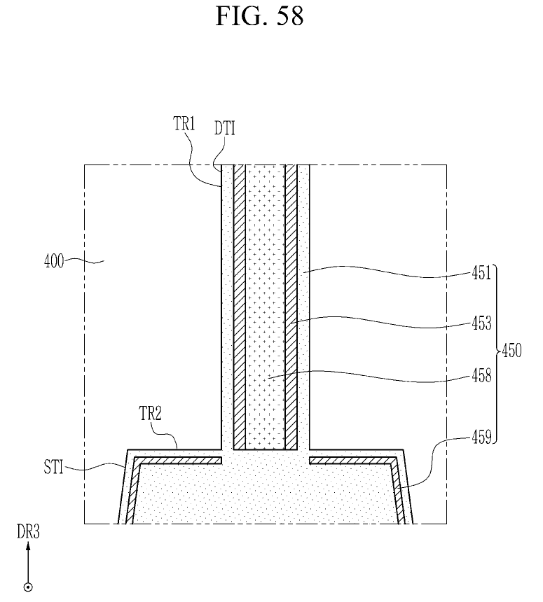

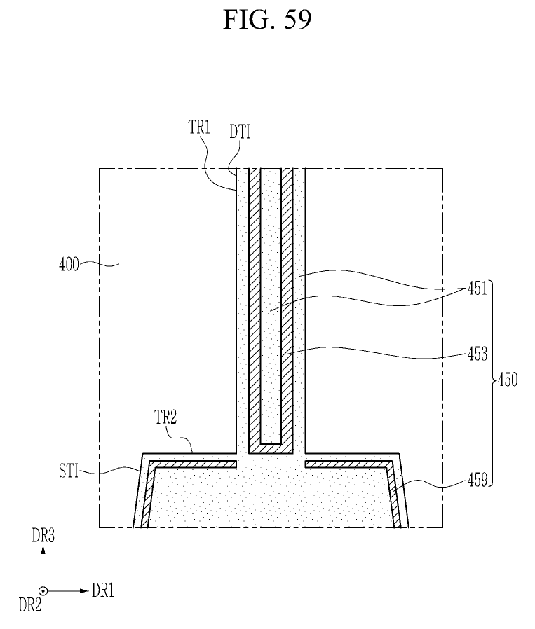

FIG. 58 shows the same cross-section as FIG. 57, with respect to one or more example embodiments. Referring to FIG. 57, an image sensor according to one or more example embodiments is the same as FIG. 55, except that the space between the second PD isolation pattern 453 is filled with the fourth PD isolation pattern 458 instead of the first PD isolation pattern 451. A duplicate detailed description of the same configuration has been omitted. The fourth PD isolation pattern 458 may include a metal or insulation layer.

FIG. 59 shows another cross-section with respect to the one or more example embodiments of FIG. 57. That is, in the image sensor according to one or more example embodiments of FIG. 59 may be a cross-section in the A-A’ direction (a same cross-section as FIG. 8), and FIG. 57 may be a cross-section in the B-B’ direction (a same cross-section as FIG. 9). Referring to FIG. 59, the space between the second PD isolation pattern 453 may be filled with the first PD isolation pattern 451. A duplicate detailed description of the same configuration has been omitted.

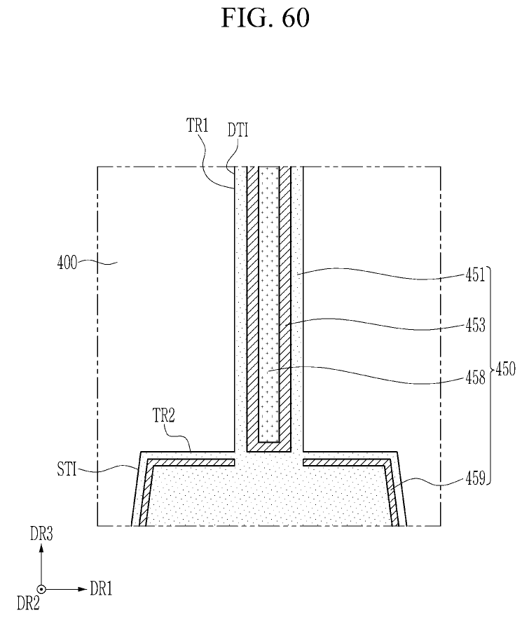

FIG. 60 shows another cross-section with respect to the one or more example embodiments of FIG. 58. That is, in the image sensor according to one or more example embodiments of FIG. 60 may be a cross-section in the A-A’ direction (same cross-section as FIG. 8), and FIG. 58 may be a cross-section in the B-B’ direction (same cross-section as FIG. 9). Referring to FIG. 60, the space between the second PD isolation pattern 453 may be filled with the fourth PD isolation pattern 458. A duplicate detailed description of the same configuration has been omitted. The fourth PD isolation pattern 458 may include a metal or insulation layer.

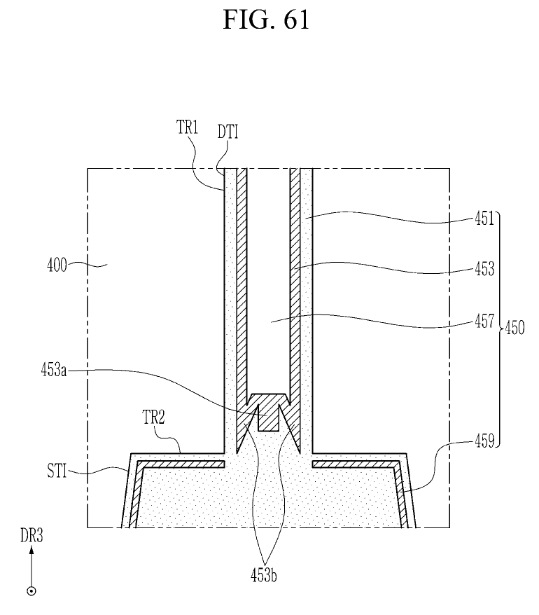

FIG. 61 shows the same cross-section as FIG. 52, with respect to one or more example embodiments. Referring to FIG. 61, an image sensor according to one or more example embodiments is the same as the one or more example embodiments of FIG. 52, except that the second PD isolation pattern 453 includes the edge portion 453b provided on the edge. A duplicate detailed description of the same configuration has been omitted. The description on the edge portion 453b is also the same as described above, and a duplicate description has been omitted.

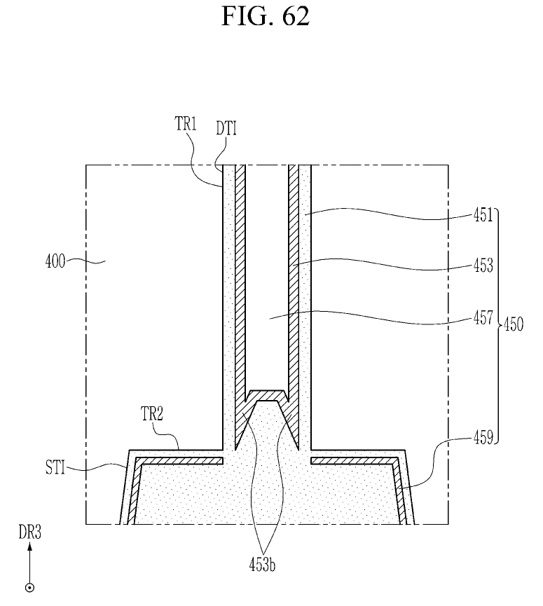

FIG. 62 shows the same cross-section as FIG. 61, with respect to one or more example embodiments. The one or more example embodiments of FIG. 62 are the same as the one or more example embodiments of FIG. 61, except that the protruding portion 453a is removed from the one or more example embodiments of FIG. 61. A duplicate detailed description of the same configuration has been omitted.

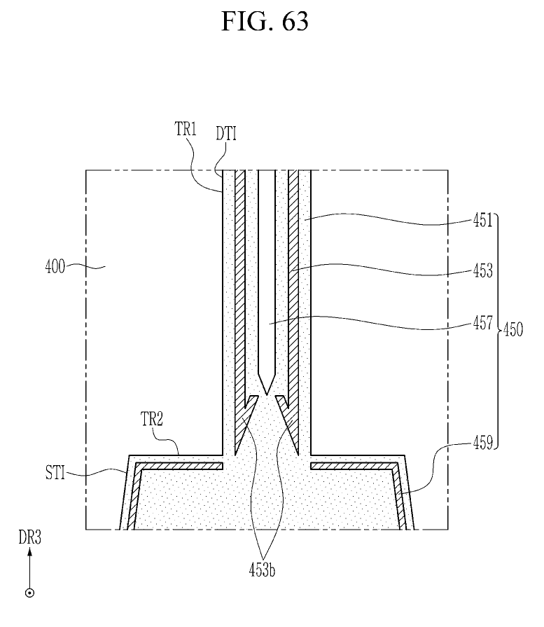

FIG. 63 shows the same cross-section as FIG. 55, with respect to one or more example embodiments. Referring to FIG. 63, an image sensor according to one or more example embodiments is the same as the one or more example embodiments of FIG. 55, except that the second PD isolation pattern 453 includes the edge portion 453b provided on the edge. A duplicate detailed description of the same configuration has been omitted. The description of the edge portion 453b is also the same as described above, and a duplicate description has been omitted.

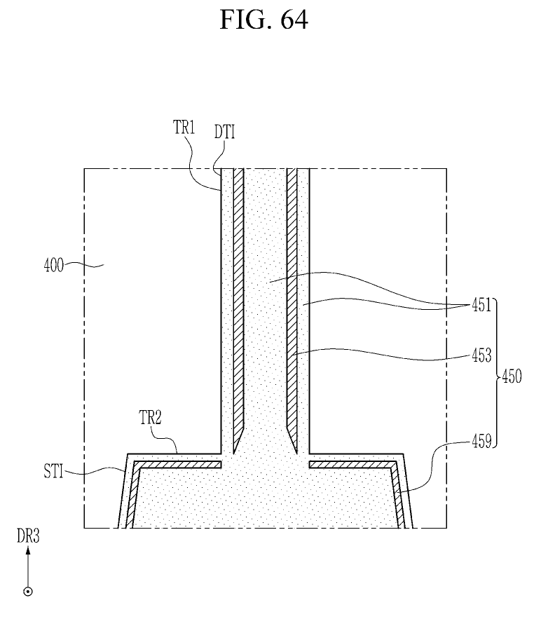

FIG. 64 shows the same cross-section as FIG. 57, with respect to one or more example embodiments. FIG. 64 is the same as FIG. 57, except that an edge of the second PD isolation pattern 453 has an inclined surface. The inclined surface shown in FIG. 64 may be a structure that is derived when the sacrificial layer 470 is not etched to be flat while etching the sacrificial layer 470, as described above. A duplicate detailed description of the same configuration has been omitted.

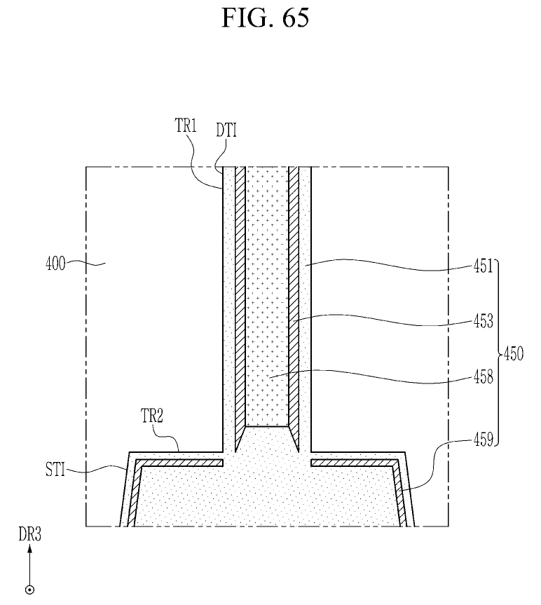

FIG. 65 shows the same cross-section as FIG. 58, with respect to one or more example embodiments. Referring to FIG. 65, an image sensor according to one or more example embodiments is the same as FIG. 58, except that an edge of the second PD isolation pattern 453 has an inclined surface. The description on the inclined surface is the same as described above. A duplicate detailed description of the same configuration has been omitted.

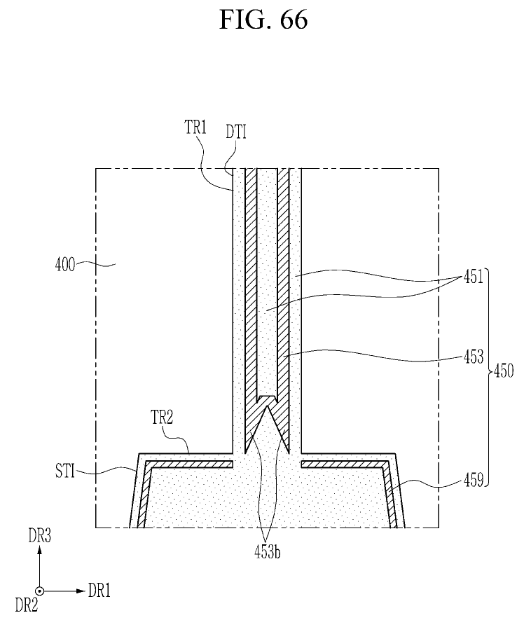

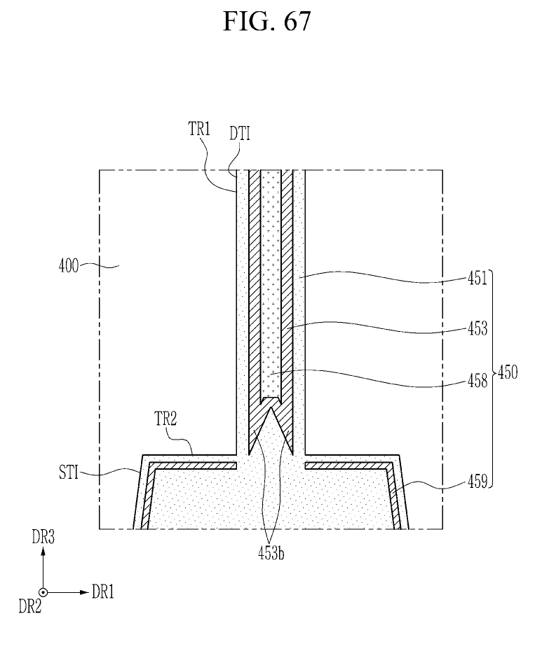

FIG. 66 shows another cross-section with respect to the one or more example embodiments of FIG. 64. That is, in the image sensor according to the same embodiment, the one or more example embodiments of FIG. 66 may be a cross-section in the A-A’ direction (same cross-section as FIG. 8), and FIG. 64 may be a cross-section in the B-B’ direction (same cross-section as FIG. 9). Referring to FIG. 66, even in the cross-section of FIG. 66, the second PD isolation pattern 453 may include the edge portion 453b, and an interior of the second PD isolation pattern 453 may be filled with the first PD isolation pattern 451.

FIG. 67 shows another cross-section with respect to the one or more example embodiments of FIG. 66. That is, in the image sensor according to one or more example embodiments of FIG. 67 may be a cross-section in the A-A’ direction (same cross-section as FIG. 8), and FIG. 65 may be a cross-section in the B-B’ direction (same cross-section as FIG. 9). Referring to FIG. 67, even in the cross-section of FIG. 67, the second PD isolation pattern 453 may include the edge portion 453b, and the interior of the second PD isolation pattern 453 may be filled with the fourth PD isolation pattern 458.

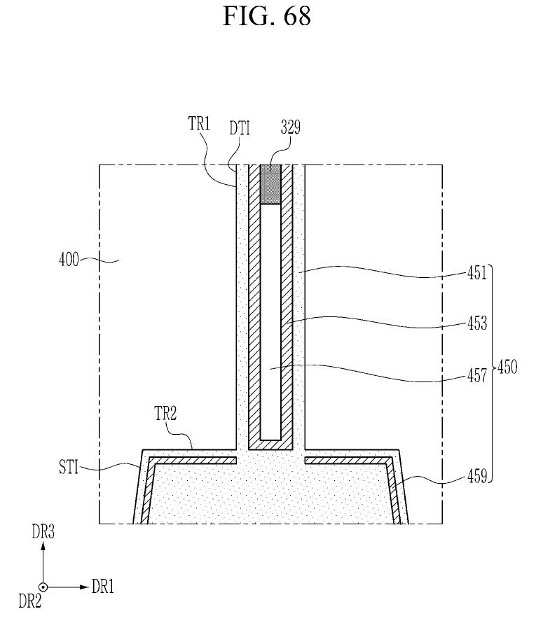

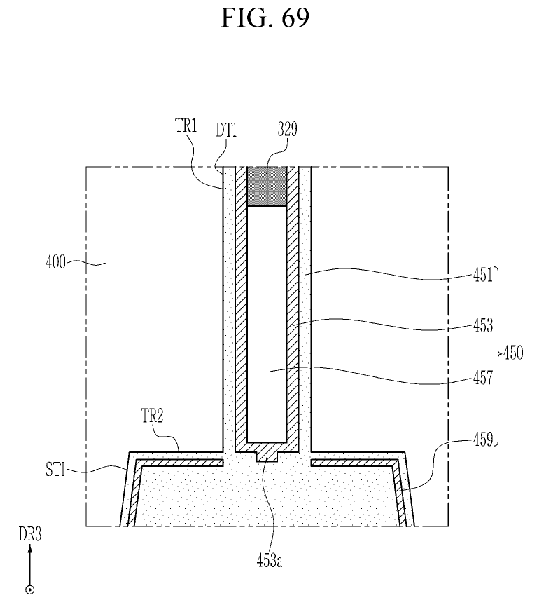

FIG. 68 illustrates the same cross-section as FIGS. 51 and 69 illustrates the same cross-section as FIG. 52, with respect to one or more example embodiments. Referring to FIGS. 68 and 69, an image sensor according to one or more example embodiments is the same as the one or more example embodiments of FIGS. 51 and 52 except that a part of the insulation structure 329 is provided within the void 457. A duplicate detailed description of the same configuration has been omitted. That is, in the process after FIGS. 32 and 33 during the manufacturing process, the insulation structure 329 may be formed in the first surface of the substrate 400, and at this time, the void 457 is exposed, such that some of the material of the insulation structure 329 may also be formed within the void 457 during the manufacturing process. However, depending on the material characteristic of the insulation structure 329, it may not be formed within the void 457. When some of the material of the insulation structure 329 is formed within the void 457, the shape may be similar to that illustrated in FIGS. 68 and 69, or may be formed along the side wall in a shape similar to the second PD isolation pattern 453.

As described above, in an image sensor according to one or more example embodiments, the second PD isolation pattern 453 including polycrystalline silicon among the PD isolation pattern 450 may have a hollow bottle shape or may be provided in a thin thickness of 4 nm to 8 nm. Accordingly, an area of the second PD isolation pattern 453 may be minimized, so that the sensitivity deterioration of an image sensor due to light absorption of polycrystalline silicon may be prevented. In the region between the second PD isolation pattern 453, a void may be provided, or an insulating material or a metal material may be provided. The space between the second PD isolation pattern 453 may be entirely filled with an insulating material or a metal material, both a void and an insulating material or a metal material may be provided, and a void may be provided without being filled with an insulating material or a metal material. Depending on the manufacturing process, the upper surface of the second PD isolation pattern 453 may be flat, or may have a protruding central portion, or may have a protruding edge portion.

According to an aspect of the disclosure, a method of manufacturing an image sensor may include: providing a substrate including a plurality of photodiode regions; providing an isolation pattern between the plurality of photodiode regions and configured to separate the substrate, wherein a surface of the substrate extends in a first direction and also extends in a second direction perpendicular to the first direction, wherein the isolation pattern is provided in a first trench penetrating the substrate in a third direction perpendicular to the surface of the substrate, wherein the providing the isolation pattern includes: providing a first isolation pattern along a side wall of the first trench; and providing a second isolation pattern insulated from the substrate by the first isolation pattern and having a hollow bottle shape, wherein a void is provided within the second isolation pattern, and wherein a thickness of the second isolation pattern in the first direction intersecting the third direction is smaller than a width of the void in the first direction.

While one or more example embodiments have been particularly shown and described above, it will be apparent to those skilled in the art that various modifications in form and details may be made therein without departing from the spirit and scope of the following claims.

What is claimed is:

1. An image sensor comprising:
a substrate comprising a plurality of photodiode regions; and
an isolation pattern provided between the plurality of photodiode regions and configured to separate the substrate,
wherein a surface of the substrate extends in a first direction and in a second direction perpendicular to the first direction,
wherein the isolation pattern is provided in a first trench penetrating the substrate in a third direction perpendicular to the surface of the substrate,
wherein the isolation pattern comprises:
a first isolation pattern provided along a side wall of the first trench; and
a second isolation pattern insulated from the substrate by the first isolation pattern and having a hollow bottle shape,
wherein a void is provided within the second isolation pattern, and
wherein a thickness of the second isolation pattern in the first direction intersecting the third direction is smaller than a width of the void in the first direction.

2. The image sensor of claim 1, wherein the thickness of the second isolation pattern in the first direction is from 4 nm to 8 nm.

3. The image sensor of claim 1, wherein the width of the void in the first direction is 3 times to 40 times greater than the thickness of the second isolation pattern in the first direction.

4. The image sensor of claim 1, wherein:
an upper surface of the second isolation pattern is without any openings; and
a lower surface of the second isolation pattern has an opening which exposes the void.

5. The image sensor of claim 4, wherein the upper surface of the second isolation pattern has a flat shape.

6. The image sensor of claim 4, wherein the upper surface of the second isolation pattern comprises a protruding portion having a protruding center.

7. The image sensor of claim 4, wherein the upper surface of the second isolation pattern comprises an edge portion having a protruding edge.

8. The image sensor of claim 1, comprising:
a transistor provided on a first surface of the substrate; and
an insulation layer provided on a second surface of the substrate,
wherein the insulation layer is partially provided in the void.

9. The image sensor of claim 1, further comprising:
a third isolation pattern; and
a fourth isolation pattern provided in the void,
wherein the fourth isolation pattern comprises a metal or an insulation layer.

10. The image sensor of claim 1, wherein:
a part of the first isolation pattern is provided in the void; and
the part of the first isolation pattern provided in the void and a part of the first isolation pattern provided outside the void are integrally connected.

11. The image sensor of claim 1, wherein the second isolation pattern comprises polycrystalline silicon.

12. An image sensor comprising:
a substrate comprising a plurality of photodiode regions; and
an isolation pattern provided between the plurality of photodiode regions and configured to separate the substrate,
wherein a surface of the substrate extends in a first direction and also extends in a second direction perpendicular to the first direction,
wherein the isolation pattern is provided in a first trench penetrating the substrate in a third direction perpendicular to the surface of the substrate,
wherein the isolation pattern comprises:
a first isolation pattern provided along a side wall of the first trench; and
a second isolation pattern insulated from the substrate by the first isolation pattern and provided along the side wall of the first trench, and
wherein, in a cross-section in the first direction, a thickness of the second isolation pattern in the first direction intersecting the third direction is thinner than a distance in the first direction between two surfaces of the second isolation pattern, which face each other.

13. The image sensor of claim 12, wherein the thickness of the second isolation pattern in the first direction is from 4 nm to 8 nm.

14. The image sensor of claim 12, wherein:
a part of the first isolation pattern is provided inside the second isolation pattern and fills the first trench; and
the part of the first isolation pattern provided inside the second isolation pattern and a part of the first isolation pattern provided outside the second isolation pattern are integrally connected.

15. The image sensor of claim 14, wherein a void is provided in the first trench.

16. The image sensor of claim 12, further comprising:
a third isolation pattern; and
a fourth isolation pattern provided inside the second isolation pattern and filling the first trench,
wherein the fourth isolation pattern comprises a metal or an insulation layer.

17. The image sensor of claim 16, wherein a void is provided in the first trench.

18. An image sensor, comprising:
a substrate comprising a plurality of photodiode regions; and
an isolation pattern provided between the plurality of photodiode regions and configured to separate the substrate,
wherein a surface of the substrate extends in a first direction and also extends in a second direction perpendicular to the first direction,
wherein the substrate comprises:
a first trench penetrating the substrate in a third direction perpendicular to the surface of the substrate; and
a second trench provided adjacent to the first trench and having a shorter length in the third direction than the first trench,
wherein the isolation pattern is provided in the first trench and the second trench,
wherein the isolation pattern comprises:
a first isolation pattern;
a second isolation pattern; and
a third isolation pattern,
wherein a void is provided in the isolation pattern,
wherein the second isolation pattern is provided in a hollow bottle shape provided in the first trench,
wherein the void is provided within the second isolation pattern,
wherein the third isolation pattern is provided along a side surface of the second trench, and
wherein the first isolation pattern is provided between the third isolation pattern and the substrate, between the second isolation pattern and the substrate, and in the second trench.

19. The image sensor of claim 18, wherein a width of the void in the first direction intersecting the third direction is 3 times to 40 times greater than a thickness of the second isolation pattern in the first direction.

20. The image sensor of claim 18, wherein a thickness of the second isolation pattern in the first direction intersecting the third direction is from 4 nm to 8 nm.
